(19) United States
(12) Patent Application Publication
(10) Pub. No.: US 2025/0275406 A1
(43) Pub. Date: Aug. 28, 2025

(54) DISPLAY APPARATUS

(71) Applicant: LG Display Co., Ltd., Seoul (KR)

(72) Inventors: Heejoong KIM, Paju-si (KR); Jaewook KWON, Paju-si (KR)

(73) Assignee: LG Display Co., Ltd., Seoul (KR)

(21) Appl. No.: 18/968,322

(22) Filed: Dec. 4, 2024

(30) Foreign Application Priority Data
Feb. 26, 2024 (KR) 10-2024-0026910

(51) Int. Cl. H10K 59/131; G09G 3/3266; H10K 59/122

(52) U.S. Cl. CPC H10K 59/1315; G09G 3/3266; H10K 59/122; G09G 2320/0233

(57) ABSTRACT

A display device may include: a display panel having a display area; a non-display area disposed outside the display area; and a first source film and a second source film attached to the non-display area. The display panel may include: a substrate; a first ground voltage supply pad disposed on the substrate and electrically connected to the first source film; a trench pixel electrode electrically connected to the first ground voltage supply pad and disposed in a trench area of the non-display area; and a cathode electrode on the substrate, and the cathode electrode may be electrically connected to the trench pixel electrode in the trench area.

### CROSS REFERENCE TO RELATED APPLICATION

The present application claims the benefit of and priority to Korean Patent Application No. 10-2024-0026910, filed Feb. 26, 2024, the entire contents of which are incorporated herein by reference for all purposes.

### BACKGROUND

### 1. Technical Field

The present disclosure relates to a display apparatus.

### 2. Description of the Related Art

With the development of the information society, there has been an increasing demand for a variety of types of image display devices. In this regard, a range of display devices, such as liquid crystal display (LCD) devices, plasma display devices, and organic light-emitting diode (OLED) display devices, have recently come into widespread use.

The display panel of the display device may include a plurality of organic light emitting devices, and the organic light emitting devices may include an anode electrode, an organic layer, and a cathode electrode. A ground voltage may be applied to the cathode electrode.

The description of the related art should not be assumed to be prior art merely because it is mentioned in or associated with this section. The description of the related art includes information that describes one or more aspects of the subject technology, and the description in this section does not limit the invention.

### SUMMARY

The inventors of the present disclosure have recognized the problems and needs of the related art, have performed extensive research and experiments, and have developed a new invention. One or more aspects of the present disclosure are directed to an apparatus that substantially obviates one or more problems due to limitations and disadvantages of the related art.

In one or more aspects, an object to be solved by the present disclosure is to provide a display device capable of improving concentration of the current and heat generation in a contact area between a ground voltage supply line and a cathode electrode by expanding the contact area between the ground voltage supply line and the cathode electrode.

The object of the present disclosure is not limited to the above-mentioned object, and other technical objects may be inferred from the embodiments described below.

One example embodiment is a display device, including: a display panel including a display area; a non-display area disposed outside the display area; and a first source film and a second source film attached to the non-display area, and the display panel may include: a substrate; a first ground voltage supply pad disposed on the substrate and for being electrically connected to the first source film; a trench pixel electrode for being electrically connected to the first ground voltage supply pad and disposed in a trench area of the non-display area; and a cathode electrode on the substrate, and the cathode electrode may be electrically connected to the trench pixel electrode in the trench area.

Another example embodiment is a display device, including: a display panel including: a display area; a non-display area disposed outside the display area; and a source film configured to supply a ground voltage to the display panel. The source film may be attached to or on the non-display area. The display panel may include: a substrate; a first ground voltage supply pad and a second ground voltage supply pad disposed on the substrate and configured to receive the ground voltage from the source film; an upper electrode disposed between the source film and the display area and for being electrically connected to the second ground voltage supply pad; a trench electrode disposed in a trench area of the non-display area and for being electrically connected to the first ground voltage supply pad; and a cathode electrode disposed on the upper electrode and the trench electrode, and the upper electrode and the trench electrode may be electrically connected to the cathode electrode.

Other details of the embodiments are included in the present disclosure.

According to example embodiments of the present disclosure, a display panel of a display device may include a ground voltage supply pad configured to receive a ground voltage from a source film, and an upper pixel electrode for being electrically connected to the ground voltage supply pad. The upper pixel electrode is configured to receive the ground voltage from a main ground voltage supply pad, and is electrically connected to a cathode electrode in an upper portion. The upper pixel electrode may be disposed between the source film and the display area. That is, between the source film and the display area (an upper area of the non-display area), a first contact area between the cathode electrode and the upper pixel electrode may be provided. However, if a contact between the upper pixel electrode and the cathode electrode is established only in the first contact area, the heat and the current may be concentrated in the area, thereby causing a fault in the display device. Therefore, according to the example embodiments of the present disclosure, a trench pixel electrode may be disposed in a trench area positioned on a left side, a right side, and a lower side of the display panel (left, right and lower areas of the non-display area), and an additional ground voltage supply pad configured to receive the ground voltage from the source film may be electrically connected to the trench pixel electrode. Further, the trench pixel electrode may come into contact with the cathode electrode. That is, a second contact area between the cathode electrode and the trench pixel electrode may be additionally provided in the left, the right, and the lower areas of the non-display area.

Therefore, a fault of the display device may be prevented in advance by distributing concentration of the heat and the current concentrated in the first contact area to the second contact area.

Further, according to the example embodiments of the present disclosure, because the concentration of the heat and the current in the first contact area is distributed to the second contact area, the lifespan of the display device may be improved.

Moreover, according to the example embodiments of the present disclosure, a gate signal supply line configured to connect a gate signal supply pad configured to receive a gate supply signal from the source film and a gate driving circuit to each other may be disposed. The source film may include a plurality of lead terminals, and the display panel may include pads corresponding to the plurality of lead terminals. The lead terminal positioned on an outer-most side among the plurality of lead terminals may be a dummy lead terminal. The lead terminal adjacent to the dummy lead terminal among the plurality of lead terminals of the source film may be a gate signal supply lead terminal configured to supply a gate signal to the gate driving circuit. The above-mentioned additional ground voltage supply pad may be connected to the dummy lead terminal among the plurality of lead terminals. That is, in order to supply the ground voltage to the additional ground voltage supply pad, the lead terminal which has been the dummy lead terminal among the plurality of lead terminals may serve as an additional ground voltage supply lead terminal configured to supply the ground voltage to the additional ground voltage supply pad. The gate signal supply lead terminal may be electrically connected to the gate signal supply pad. The additional ground voltage supply pad may be disposed outside the gate signal supply pad. The additional ground voltage supply pad and the gate signal supply pad may be electrically connected to the trench pixel electrode and the gate driving circuit through respective lines. The trench area in which the trench pixel electrode is disposed may be positioned outside the gate driving circuit.

The additional ground voltage supply pad is disposed outside the gate signal supply pad, and the trench area in which the trench pixel electrode is disposed is disposed outside the gate driving circuit; therefore, the additional ground voltage supply line and the gate signal supply line inevitably intersect each other. Accordingly, according to the example embodiments of the present disclosure, in an area in which the additional ground voltage supply line and the gate signal supply line intersect each other, the additional ground voltage supply line may prevent a short circuit with the gate signal supply line by using a conductive layer which is different from a conductive layer at or in which the gate signal supply line is disposed.

The effects of the present invention are not limited to the above-described effects and other effects which are not described herein may be derived by those skilled in the art from the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure.

FIG. 1 is a view schematically illustrating a display device according to a first example embodiment.

FIG. 2 is an example system diagram of a display device according to a first example embodiment.

FIG. 3 is an example circuit diagram of a sub-pixel in a display device according to a first example embodiment.

FIG. 4 is an example of a plan view of an arrangement of a display device according to FIG. 2.

FIG. 5 is an example of an enlarged plan view of a Q1 area of FIG. 4.

FIG. 6 is an example of a cross-sectional view taken along A-A′ line of FIG. 5.

FIG. 7 is an example of a cross-sectional view taken along B-B′ of FIG. 5.

FIG. 8 is an example of a cross-sectional view taken along C-C′ line of FIG. 5.

FIG. 9 is an example of a cross-sectional view taken along D-D′ line of FIG. 5.

FIG. 10 is an example of a cross-sectional view taken along E-E′ line of FIG. 5.

FIG. 11 is a cross-sectional view of a display device according to a comparative embodiment.

FIG. 12 is a schematic view illustrating concentration of the heat in a display device according to a comparative embodiment.

FIG. 13 is a plan view of a display device according to a second example embodiment.

FIG. 14 is an example of a cross-sectional view taken along D-D′ line of FIG. 13.

FIG. 15 is a plan view of a display device according to a third example embodiment.

FIG. 16 is an example of a cross-sectional view taken along F-F′ line of FIG. 15.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, circuits, pads, electrodes, lines, parts, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, circuits, pads, electrodes, lines, parts, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like (including, for examples, “1-1,” “1-2,” “1-3,” “2-1,” “2-2,” “first-first,” “first-second,” “first-third,” “second-first,” “second-second,” and the like) may be used herein to describe various elements (e.g., layers, films, components, circuits, pads, electrodes, lines, parts, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, component, circuit, pad, electrode, line, part, area, portion, or the like) is “crossing,” “intersecting,” “connected,” “coupled,” “attached,” “adhered,” “combined,” “linked,” or the like another element or to another element, the element can not only be directly crossing, intersecting, connected, coupled, attached, adhered, combined, linked, or the like another element or to another element, but also be indirectly crossing, intersecting, connected, coupled, attached, adhered, combined, linked, or the like another element or to another element with one or more intervening elements disposed or interposed between the elements, unless otherwise specified.

For the expression that an element (e.g., layer, film, component, circuit, pad, electrode, line, part, area, portion, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phrase that an element (e.g., layer, film, component, circuit, pad, electrode, line, part, area, portion, or the like) is “provided,” “disposed,” “connected,” “coupled,” or the like in, on, with or to another element may be understood, for example, as that at least a portion of the element is provided, disposed, connected, coupled, or the like in, on, with or to at least a portion of another element. The phrase “through” may be understood, for example, to be at least partially through or entirely through. The phrase that an element (e.g., layer, film, component, circuit, pad, electrode, line, part, area, portion, or the like) “contacts,” “overlaps,” or the like with another element may be understood, for example, as that at least a portion of the element contacts, overlaps, or the like with a least a portion of another element.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item.

The expression of a first element, a second elements “and/of” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, component, circuit, pad, electrode, line, part, area, portion, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

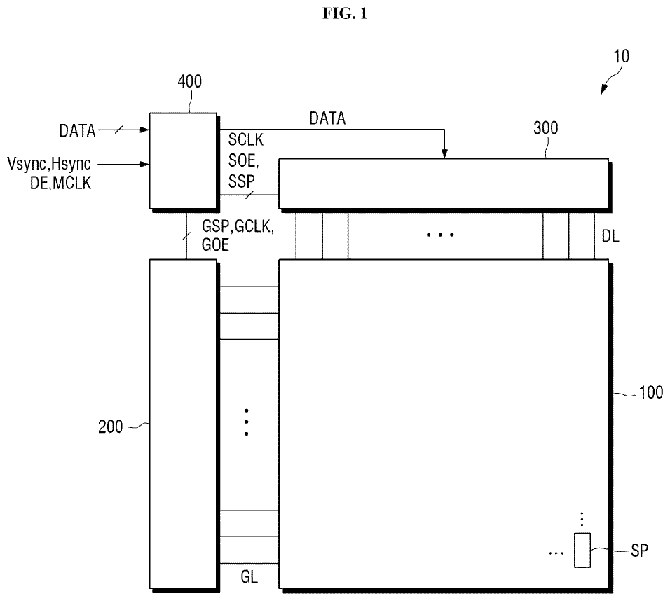

FIG. 1 is a view schematically illustrating a display device according to a first example embodiment.

Referring to FIG. 1, the display device 10 according to the first example embodiment of the present disclosure may include a display panel 100 connected to a plurality of gate lines GL and a plurality of data lines DL in which a plurality of subpixels SP are arranged in a form of a matrix, a gate driving circuit 200 for supplying scan signals to the plurality of gate lines GL and a data driving circuit 300 for supplying data voltages through the plurality of data lines DL, and a timing controller 400 for controlling the gate driving circuit 200 and the data driving circuit 300.

The display panel 100 displays an image based on the scan signals supplied from the gate driving circuit 200 through the plurality of gate lines GL and the data voltages supplied from the data driving circuit 300 through the plurality of data lines DL.

In the case of a liquid crystal display, the display panel 100 includes a liquid crystal layer formed between two substrates, and may be operated in any known mode such as TN (Twisted Nematic) mode, VA (Vertical Alignment) mode, IPS (In Plane Switching) mode, FFS (Fringe Field Switching) mode. On the other hand, in the case of an organic light emitting display, the display panel 100 may be implemented in a top emission method, a bottom emission method, or a dual emission method.

In the display panel 100, a plurality of pixels may be disposed in a matrix form. Each pixel may be composed of subpixels SP of different colors, for example, a white subpixel, a red subpixel, a green subpixel, and a blue subpixel. Each subpixel SP may be defined by the plurality of the data lines DL and the plurality of the gate lines GL.

A subpixel SP may include a thin film transistor (TFT) arranged in an area which is formed by a data line DL and a gate line GL, a light emitting element such as a light emitting diode which is emitted according to the data voltage, and a storage capacitor for maintaining the data voltage by being electrically connected to the light emitting element.

For example, when the display device 10 having a resolution of 2,600×3,840 includes four subpixels SP of white W, red R, green G, and blue B, 3,840×4=15,360 data lines DL may be provided by 2,600 gate lines GL and 3,840 data lines DL respectively connected to 4 subpixels WRGB. Each of the plurality of subpixels SP may be disposed in areas formed by the gate lines GL and the data lines DL.

The gate driving circuit 200 is controlled by the timing controller 400, and controls the driving timing of the plurality of subpixels SP by sequentially supplying the scan signals to the plurality of gate lines GL disposed in the display panel 100.

In the display device 10 having a resolution of 2,600×3,840, an operation of sequentially supplying the scan signals to the 2,600 gate lines GL from the first gate line GL1 to the 2,600th gate line GL may be referred to as 2,600-phase driving operation. Otherwise, an operation of sequentially supplying the scan signals to every four gate lines GL, as in a case in which the scan signals are supplied sequentially from a first gate line GL1 to a fourth gate line GL4, and then are supplied sequentially from a fifth gate line GL5 to an eighth gate line GL8, may be referred to as 4-phase driving operation. That is, an operation in which the scan signals are supplied sequentially to every N number of gate lines may be referred as a N-phase driving operation.

At this time, the gate driving circuit 200 may include one or more gate driving integrated circuits (GDIC), which may be disposed on one side or both sides of the display panel 100 depending on the driving method. Alternatively, the gate driving circuit 200 may be implemented in a gate-in-panel (GIP) structure embedded in a bezel area of the display panel 100.

The data driving circuit 300 receives digital image data DATA from the timing controller 400, and converts the received digital image data DATA into an analog data voltage. Then, the data driving circuit 300 supplies the analog data voltage to each of the data lines DL at time which the scan signal is supplied through the gate line GL, so that each of the subpixels SP connected to the data lines DL emits light with a corresponding luminance in response to the analog data voltage.

Likewise, the data driving circuit 300 may include one or more source driving integrated circuits (SDIC). Each of the source driving integrated circuits SDIC may be connected to a bonding pad of the display panel 100 by a tape automated bonding (TAB) or a chip on glass (COG), or may be directly mounted on the display panel 100.

In some cases, each of the source driving integrated circuits SDIC may be integrated with the display panel 100. In addition, each of the source driving integrated circuits SDIC may be implemented with a chip on film (COF) structure. In this case, the source driving integrated circuit SDIC may be mounted on circuit film to be electrically connected to the data lines DL in the display panel 100 via the circuit film.

The timing controller 400 supplies various control signals to the gate driving circuit 200 and the data driving circuit 300, and controls the operations of the gate driving circuit 200 and the data driving circuit 300. That is, the timing controller 400 controls the gate driving circuit 200 to supply the scan signals in response to a time realized by respective frames, and on the other hand, transmits the digital image data DATA from an external source to the data driving circuit 300.

Here, the timing controller 400 receives various timing signals, including a vertical synchronization signal Vsync, a horizontal synchronization signal Hsync, a data enable signal DE, and a main clock MCLK, from an external source (e.g., a host system). Accordingly, the timing controller 400 generates control signals using the various timing signals received from the external source, and supplies the control signals to the gate driving circuit 200 and the data driving circuit 300.

For example, the timing controller 400 generates various gate control signals, including a gate start pulse GSP, a gate clock GCLK, and a gate output enable signal GOE, to control the gate driving circuit 200. Here, the gate start pulse GSP is used to control the start timing of one or more gate driving integrated circuits GDIC of the gate driving circuit 200. In addition, the gate clock GCLK is a clock signal commonly supplied to the one or more gate driving integrated circuits GDIC for controlling the shift timing of the scan signals. The gate output enable signal GOE designates timing information of the one or more gate driving integrated circuits GDIC.

In addition, the timing controller 400 generates various data control signals, including a source start pulse SSP, a source sampling clock SCLK, and a source output enable signal SOE, to control the data driving circuit 300. Here, the source start pulse SSP is used to control the start timing for the data sampling of one or more source driving integrated circuits SDIC of the data driving circuit 300. The source sampling clock SSC is a clock signal for controlling a timing of data sampling in each of the source driving integrated circuits SDIC. The source output enable signal SOE controls the output timing of the data driving circuit 300.

The display device 10 may further include a power management integrated circuit for supplying or controlling various voltage or current to the display panel 100, the gate driving circuit 200, and the data driving circuit 300.

Meanwhile, a light emitting element may be disposed in each of the subpixels SP. For example, the organic light emitting display device may include a light emitting element, such as a light emitting diode in each of the subpixels SP, and may display an image by controlling current flowing through the light emitting elements in response to the data voltage.

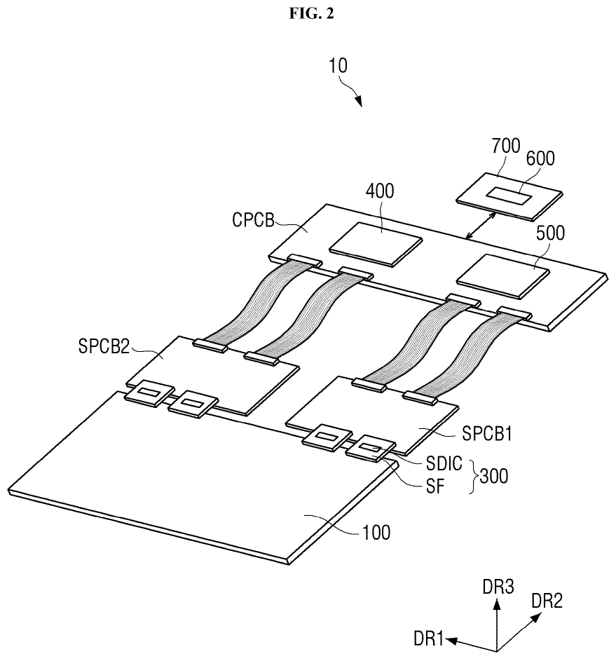

FIG. 2 is an example system diagram of the display device according to the first example embodiment.

FIG. 2 illustrates that each of the source driving integrated circuits SDIC of the data driving circuit 300 in the display device 10 according to aspects of the present disclosure is implemented with a COF type among various structures such as a TAB, a COG, and a COF, and the gate driving circuit 200 is implemented with a GIP (Gate In Panel) type among various structures such as a TAB, a COG, a COF, and a GIP.

When the gate driving circuit 200 is implemented in a GIP type, the plurality of gate driving integrated circuits GDIC of the gate driving circuit 200 may be directly formed in a bezel area of the display panel 100. At this time, the gate driving integrated circuits GDIC may receive various signals (e.g., clock signal, gate high signal, gate low signal, etc.) necessary for generating the scan signal through the signal lines related to gate driving operation arranged in the bezel area.

Likewise, the data driving circuit 300 may include one or more source driving integrated circuits SDIC, which may be mounted on a source film SF, respectively. In addition, electrical lines may be disposed on the source films SF to electrically connect the source driving integrated circuits SDIC and the display panel 100.

The display device 10 may include at least one source printed circuit board SPCB in order to connect the plurality of source driving integrated circuits SDIC to other devices by electrical circuit, and a control printed circuit board CPCB in order to mount various control components and electric elements.

At this time, the other portion of the source film SF, on which the source driving integrated circuit SDIC is mounted, may be connected to the at least one source printed circuit board SPCB. That is, one portion of source film SF, on which the source driving integrated circuit SDIC is mounted, may be electrically connected to the display panel 100, and the other portion of the source film SF may be electrically connected to the source printed circuit board SPCB. For example, a plurality of source films SF may be connected to one source printed circuit board SPCB, but is not limited thereto.

The timing controller 400 and a power management integrated circuit 500 may be mounted on the control printed circuit board CPCB. The timing controller 400 may control the operations of the data driving circuit 300 and the gate driving circuit 200. The power management integrated circuit 500 may supply a driving voltage and a driving current, or control a voltage and a current for the display panel 100, the data driving circuit 300 and the gate driving circuit 200.

At least one source printed circuit board SPCB and the control printed circuit board CPCB may have circuitry connection by at least one connecting member. The connecting member may be, for example, a flexible printed circuit FPC, a flexible flat cable FFC, or the like. For example, the source printed circuit board SPCB may be in plural, and the plurality of source printed circuit boards SPCB may be connected to one control printed circuit board CPCB. In this case, the one source printed circuit board SPCB and the control printed circuit board CPCB may be connected to the control printed circuit board CPCB through a plurality of flexible flat cables FFC. In FIG. 2, as an example, two source printed circuit boards SPCB, four flexible flat cables FFC, and one control printed circuit board CPCB are illustrated, but are not limited thereto.

The display device 10 may further include a set board 700 electrically connected to the control printed circuit board CPCB. The set board 700 may also be referred to as a power board. A main power management circuit M-PMC 600 managing overall power of the display device 10 may be located on the set board 700. The main power management circuit 600 may be interoperated with the power management integrated circuit 500.

In the display device 10 having the above-described configuration, a driving voltage is generated by the set board 700 to be supplied to the power management integrated circuit 500. The power management integrated circuit 500 supplies the driving voltage, which is required for a display driving operation or a sensing operation of the characteristic value, to the source printed circuit board SPCB through the flexible printed circuit FPC or the flexible flat cable FFC. The driving voltage supplied to the source printed circuit board SPCB, is transmitted to emit or sense a specific subpixel SP in the display panel 100 via the source driving integrated circuits SDIC.

Each of the subpixels SP arranged in the display panel 100 of the display device 10 may include a light emitting element and circuit elements, such as a driving transistor to drive it.

The type and number of the circuit elements constituting each of the subpixels SP may be variously determined depending on the function, the design, or the like.

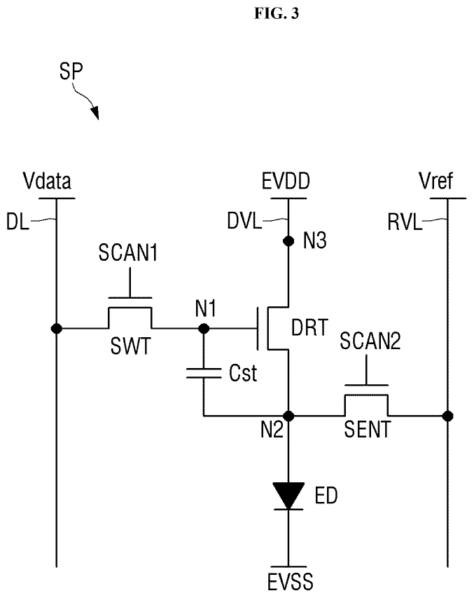

FIG. 3 is an example circuit diagram of a sub-pixel in the display device according to the first example embodiment.

Referring to FIG. 3, each of the subpixels SP arranged in the display device 10 according to the first example embodiment may include one or more transistors and a capacitor, and an organic light emitting diode as a light emitting diode ED.

For example, a subpixel SP may include a driving transistor DRT, a switching transistor SWT, a sensing transistor SENT, a storage capacitor Cst, and a light emitting diode ED.

The driving transistor DRT may have a first node N1, a second node N2, and a third node N3. The first node N1 of the driving transistor DRT may be a gate node configured to receive a data voltage Vdata applied from the data driving circuit 300 through a data line DL when the switching transistor SWT is turned on. The second node N2 of the driving transistor DRT may be electrically connected to an anode electrode of the light emitting diode ED, and may be a drain node or a source node. The third node N3 of the driving transistor DRT may be electrically connected to a driving voltage line DVL to be supplied with a driving voltage EVDD, and may be a source node or a drain node.

Here, the driving voltage EVDD for displaying an image may be supplied to the driving voltage line DVL in the display driving period. For example, the driving voltage EVDD for displaying the image may be about 27V.

The switching transistor SWT is electrically connected between the first node N1 of the driving transistor DRT and the data line DL, and operates in response to a scan signal SCAN supplied thereto through the gate line GL connected to the gate node. In addition, the switching transistor SWT controls the operation of the driving transistor DRT by transmitting the data voltage Vdata through the data line DL to the gate node of the driving transistor DRT when the switching transistor SWT is turned on.

The sensing transistor SENT is electrically connected between the second node N2 of the driving transistor DRT and a reference voltage line RVL, and operates in response to a sense signal SENSE supplied through the gate line GL connected to the gate node. When the sensing transistor SENT is turned on, a reference voltage Vref for sensing supplied through the reference voltage line RVL is transmitted to the second node N2 of the driving transistor DRT.

That is, the voltages of the first node N1 and the second node N2 of the driving transistor DRT may be controlled by controlling the switching transistor SWT and the sensing transistor SENT. Consequently, a current for emitting the light emitting diode ED may be supplied.

Each gate node of the switching transistor SWT and the sensing transistor SENT may be connected to a single gate line GL or to different gate lines GL. Here, it illustrates an example structure of which the switching transistor SWT and the sensing transistor SENT are connected to different gate lines GL. In this case, the switching transistor SWT and the sensing transistor SENT are controlled independently by the scan signal SCAN and the sense signal SENSE transmitted from the different gate lines GL.

On the other hand, when the switching transistor SWT and the sensing transistor SENT are connected to a single gate line GL, the switching transistor SWT and the sensing transistor SENT may be controlled simultaneously through the scan signal SCAN or the sense signal SENSE transmitted from the single gate line GL, and thus the aperture ratio of the subpixels SP may be improved.

In addition, the transistors disposed in the subpixels SP may be not only n-type transistors, but also p-type transistors. Herein, it illustrates the example structure of the n-type transistors.

The storage capacitor Cst is electrically connected between the first node N1 and the second node N2 of the driving transistor DRT, and serves to maintain the data voltage Vdata during a frame.

Such a storage capacitor Cst may be connected between the first node N1 and the third node N3 of the driving transistor DRT according to a type of the driving transistor DRT. The anode electrode of the light emitting diode ED may be electrically connected to the second node N2 of the driving transistor DRT, and a ground voltage EVSS may be supplied to a cathode electrode of the light emitting diode ED.

Here, the ground voltage EVSS may be the ground voltage or a voltage higher or lower than the ground voltage. In addition, the ground voltage EVSS may be varied depending on the driving condition. For example, the ground voltage EVSS during the display driving period may be set different from the ground voltage EVSS during the sensing period.

The structure of the subpixel SP as described above has a 3T1C structure comprised of three transistors and one capacitor. However, this is merely for illustrative purposes, and one or more transistors, or in some cases, one or more capacitors may be further included. Alternatively, the plurality of subpixels SP may have the same structure, or some of the plurality of subpixels SP may have a structure different from the remaining subpixels.

The display device 10 according to the first example embodiment may use a method for measuring a current flowing by voltage charged in the storage capacitor Cst during a sensing period for the driving transistor DRT in order to sense the characteristics of the driving transistor DRT like threshold voltage or mobility. Such a method may be referred to as current sensing.

That is, the characteristic value or the change of the characteristic value of the driving transistor DRT in the subpixel SP may be determined by measuring the current flowing by voltage charged in the storage capacitor Cst during the sensing period of the driving transistor DRT.

At this time, the reference voltage line RVL may be referred to as a sensing line since the reference voltage line RVL serves not only to supply the reference voltage Vref but also serves as a sensing line for sensing the characteristic value of the driving transistor DRT in the subpixel SP.

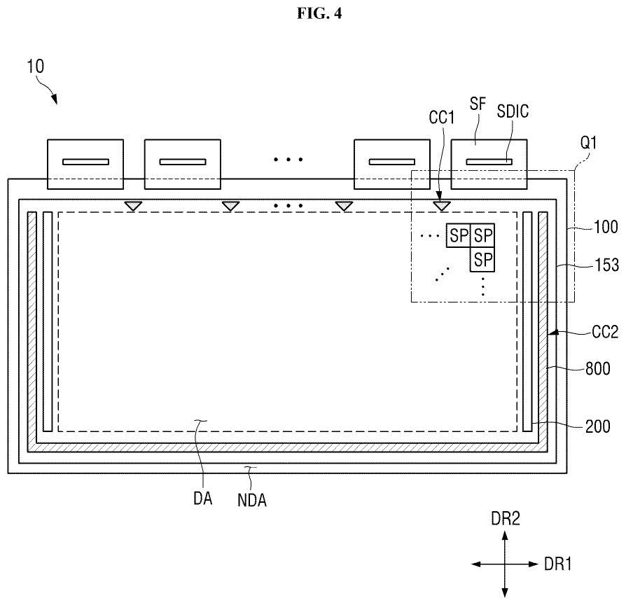

FIG. 4 is an example of a plan view of an arrangement of the display device according to FIG. 2.

Referring to FIGS. 1 to 4, the display device 100 may include long sides extending along a first direction DR1 and short sides extending along a second direction DR2. The display device 100 may have a rectangular shape which includes long sides and short sides on a plane, but is not limited thereto.

The display panel 100 includes a display area DA and a non-display area NDA around the display area DA. The display area DA includes a plurality of subpixels SP. The non-display area NDA may be disposed on one side (or a right side) in the first direction DR1 of the display area DA, on the other (or a left side) in the first direction DR1 of the display area DA, on one side (or an upper side) in the second direction DR2 of the display area DA, or on the other side (or a lower sided) in the second direction DR2 of the display area DA.

In the non-display area NDA on an upper portion of the display area DA of the display panel 100, a source film SF may be attached. The source film SF may be provided in plural, and the plurality of source films SF may be spaced apart from each other in the first direction DR1. A source driving integrated circuit SDIC may be disposed in the source film SF. The SDIC may provide a data voltage, a gate control signal, a ground voltage, or a driving voltage through lead terminals of the source film SF to the display panel 100, without limitation thereto. The ground voltage or the driving voltage may be provided from the source printed circuit board SPCB described with reference to FIG. 2 to the display panel 100 through the source film SF, however, may not be provided to the source driving integrated circuit SDIC.

In the non-display area NDA on the right or left side of the display area DA, the gate driving circuit 200 may be disposed. The gate driving circuit 200 may be provided two in number, and each of which may be disposed in the non-display area NDA on a left or a right side of the display area DA. In FIG. 4, the gate driving circuit 200 is illustrated to be two in number, but is not limited thereto, and may be disposed in any one among the non-display area NDA on the left side or the right side of the display area DA.

The display panel 100 may further include a trench area 800 disposed in the non-display area DNA on right, lower, and left sides of the display area DA. The trench area 800 may be integrally formed in the non-display area NDA on right, lower, and left sides of the display area DA, but is not limited thereto.

The gate driving circuit 200 may be disposed between the trench area 800 and the display area DA in the non-display area NDA on the right and left sides of the display area DA. The trench area 800 may serve to prevent outside air or humidity introduced from the outside of the display panel 100 from being applied to the display area DA. In the trench area 800, a substrate, at least one inorganic layer on the substrate, and a trench electrode on the at least one inorganic layer may be disposed.

The display panel 100 may include a cathode electrode 153 of a light emitting part. The cathode electrode 153 may be disposed in the display area DA. The cathode electrode 153 may be disposed to extend to the non-display area NDA. For example, the cathode electrode 153 may be disposed to extend to the non-display area NDA on the upper, right, lower, and left sides of the display area DA. The ground voltage may be supplied to the cathode electrode 153. For example, the ground voltage may be supplied to the cathode electrode 153 from the source film SF. For example, the ground voltage may be supplied to the cathode electrode 153 through the source film SF, a ground voltage supply pad in the display panel 100, and a pixel electrode. For example, the ground voltage supply pad may include a main ground voltage supply pad and an additional ground voltage supply pad, and the pixel electrode may include an upper pixel electrode and a trench pixel electrode. The main ground voltage supply pad may be disposed in an end of each source film SF. The main ground voltage supply pad of an adjacent source film SF may be electrically connected to the upper pixel electrode. The upper pixel electrode may be disposed between the adjacent source films SF. The upper pixel electrode may be disposed between the source film SF and the display area DA. Hereinafter, an area in which the upper pixel electrode and the cathode electrode 153 contact each other is referred to as a first contact area CC1.

However, if a contact between the cathode electrode 153 and the upper pixel electrode is concentrated in the first contact area CC1, that may cause the heat and the current to be concentrated in the first contact area CC1.

The display device 10 according to the first example embodiment may further include a second contact area CC2 in which the cathode electrode 153 and the trench pixel electrode contact each other. The second contact area CC2 may be disposed throughout the trench area 800. As the trench pixel electrode and the cathode electrode 153 contact each other additionally in the second contact area CC2, a problem of the concentration of the heat and the current in the first contact area CC1 may be prevented in advance.

Hereinafter, the first contact area CC1, and the second contact area CC2 will be described in more detail.

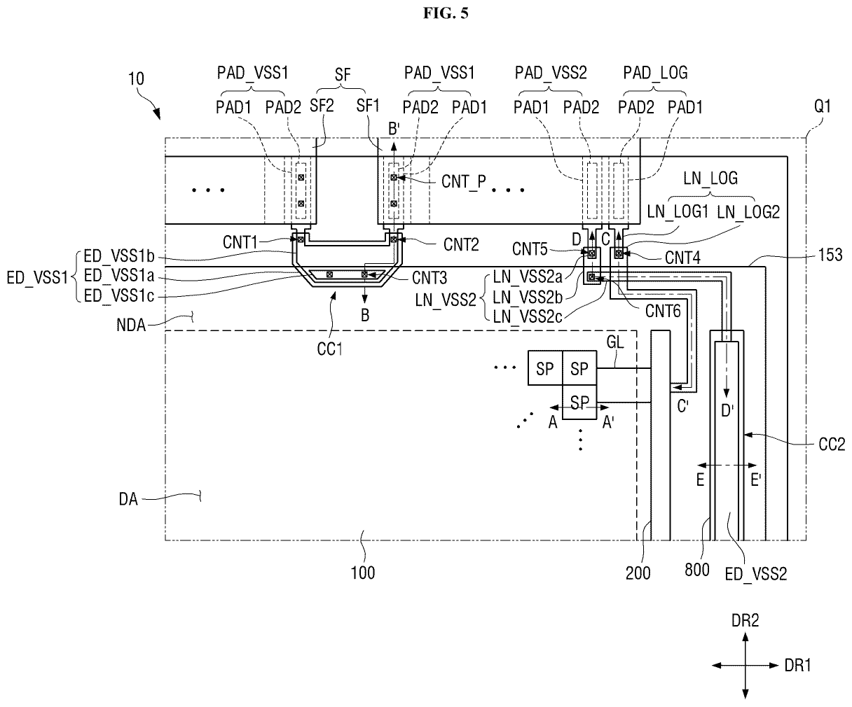

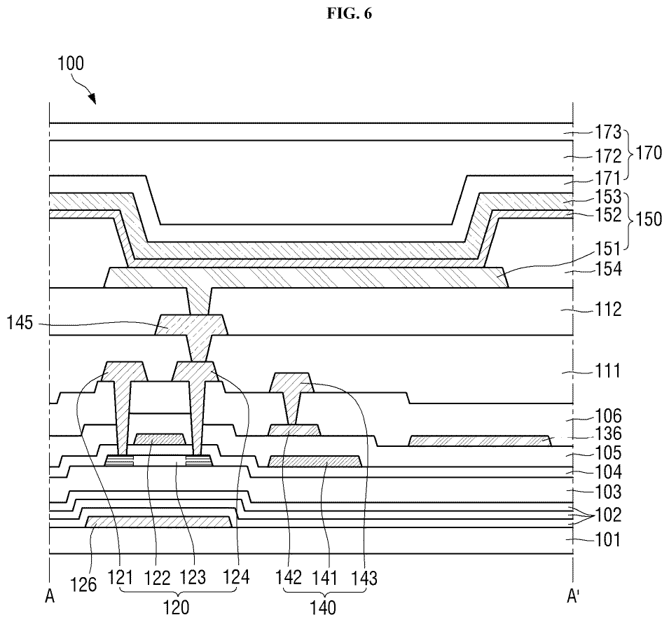

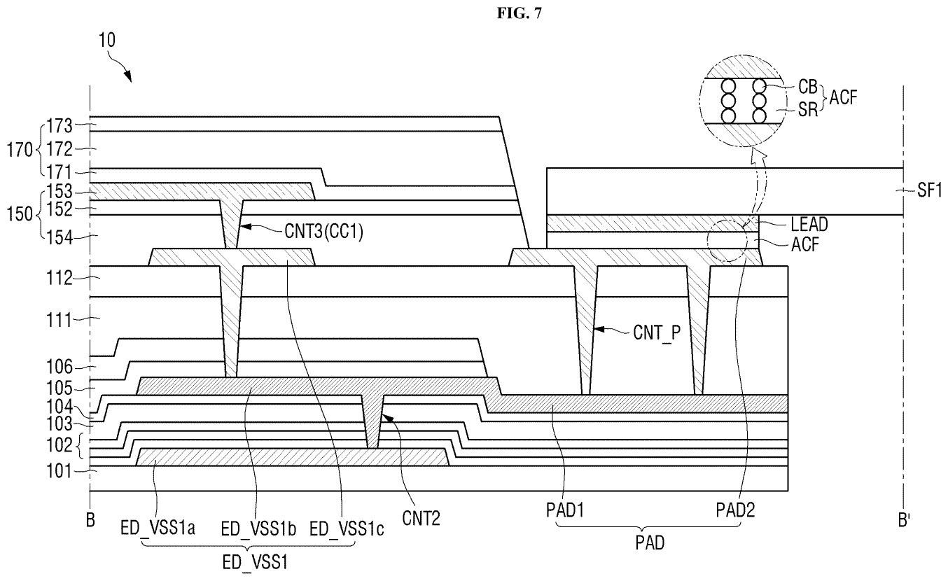

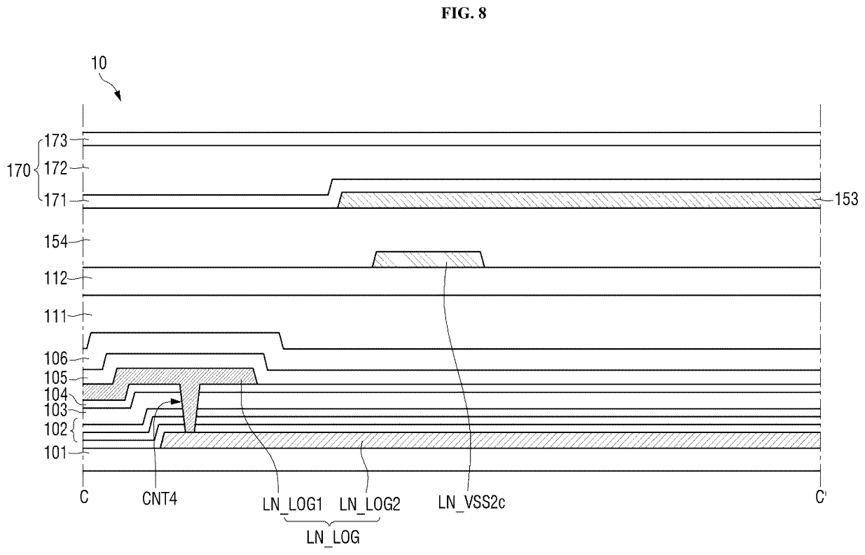

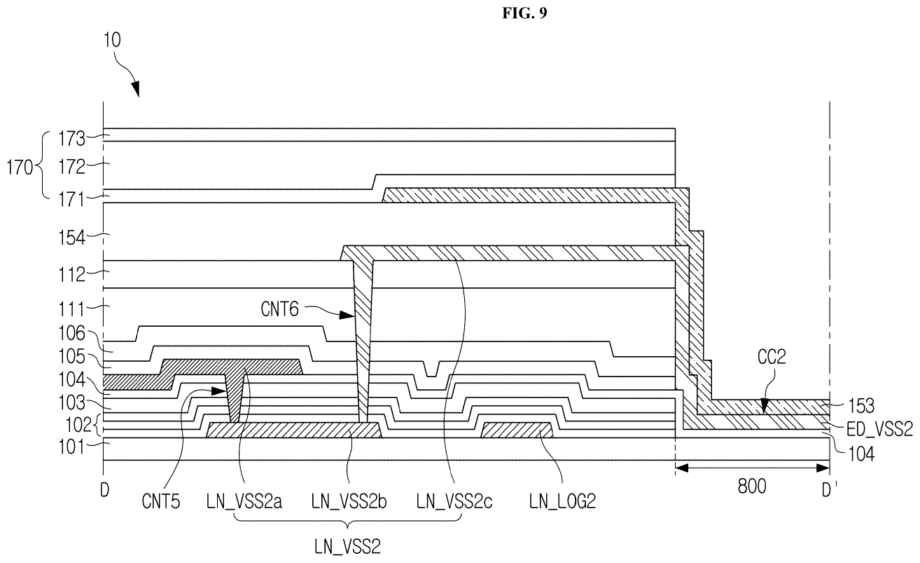

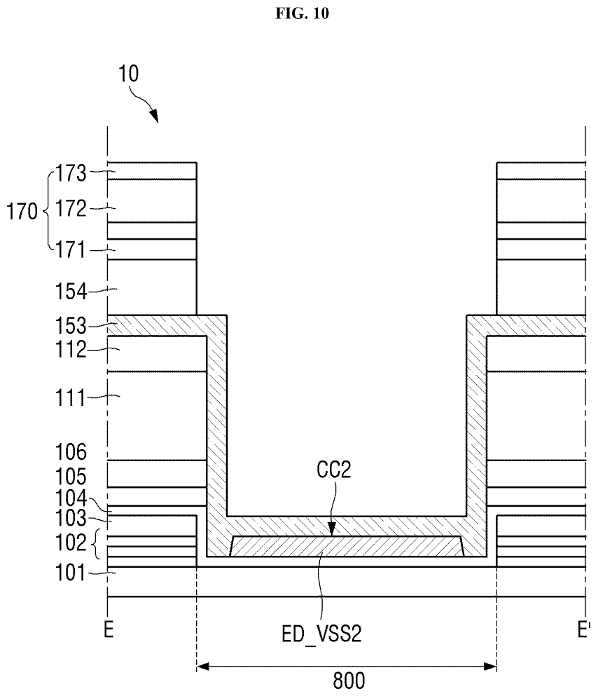

FIG. 5 is an example of an enlarged plan view of a Q1 area of FIG. 4. FIG. 6 is an example of a cross-sectional view taken along A-A′ line of FIG. 5. FIG. 7 is an example of a cross-sectional view taken along B-B′ of FIG. 5. FIG. 8 is an example of a cross-sectional view taken along C-C′ line of FIG. 5. FIG. 9 is an example of a cross-sectional view taken along D-D′ line of FIG. 5. FIG. 10 is an example of a cross-sectional view taken along E-E′ line of FIG. 5.

Referring to FIGS. 1 to 10, the display area DA may include a plurality of subpixels SP. The plurality of subpixels SP may be electrically connected to the gate lines GL extending from the gate driving circuit 200.

Referring to FIG. 6, the display panel may include a substrate 101, a first thin film transistor 120, a storage electrode 140, the light emitting part 150, an encapsulation part 170, and a touch part 180.

The substrate 101 may include one or more plastic materials. For example, the substrate 101 may be a multi-substrate which includes a plurality of plastic materials such as polyimide etc., but the embodiments of the present disclosure are not limited thereto.

On the substrate 101, a first light shielding layer 126 may be disposed. Hereinafter, a conductive layer at or in which the first light shielding layer 126 is disposed may be referred to as a first conductive layer. The first light shielding layer 126 may prevent light from penetrating a first semiconductor layer 123 of the first thin film transistor 120. For example, the first semiconductor layer 123 may overlap the first light shielding layer 126. The first light shielding layer 126 may be a single layer or a multi-layer formed of one among molybdenum (Mo), aluminum (Al), Chrome (Cr), nickel (Ni), neodymium (Nd), and copper (Cu), or an alloy of any of these materials, but the embodiments of the present disclosure are not limited thereto.

A buffer layer 102 may be disposed on the first light shielding layer 126. The buffer layer 102 may minimize or reduce distribution of water or oxygen permeating the substrate 101. The buffer layer 102 may be formed by alternately depositing a silicon nitride (SiNx) layer and a silicon oxide (SiOx) layer, each being deposited at least one time or more, but the embodiments of the present disclosure are not limited thereto.

A first insulation layer 103 may be disposed on the buffer layer 102. The first insulation layer 103 may prevent a short circuit between components of the first thin film transistor 120 and the first light shielding layer 126. The first insulation layer 103 may be formed of the same material as that of the buffer layer 102, but the embodiments of the present disclosure are not limited thereto. For example, the first insulation layer 103 may be formed of inorganic materials such as silicon nitride (SiNx) or silicon oxide (SiOx), but the embodiments of the present disclosure are not limited thereto.

The first thin film transistor 120 may be disposed on the first insulation layer 103. The first thin film transistor 120 may include a first source electrode 121, a first gate electrode 122, the first semiconductor layer 123, and a first drain electrode 124.

The first semiconductor layer 123 may be disposed on the first insulation layer 103. The first semiconductor layer 123 may contain an oxide semiconductor such as indium gallium zinc oxide (IGZO), or materials such as amorphous silicon, low temperature polycrystalline silicon, or polycrystalline silicon, but the embodiments of the present disclosure are not limited thereto. The first semiconductor layer 123 may include a channel region, a source region, and a drain region.

Since the low temperature polycrystalline silicon semiconductor layer, or the polycrystalline silicon semiconductor layer has a higher mobility as compared to an amorphous semiconductor layer and an oxide semiconductor layer, the low temperature polycrystalline silicon semiconductor layer, or the polycrystalline silicon semiconductor layer may have low energy consumption and excellent reliability. Due to these advantages, the driving transistor may be formed of the low temperature polycrystalline silicon semiconductor layer, or the polycrystalline silicon semiconductor layer, but the embodiments of the present disclosure are not limited thereto.

A second insulation layer 104 may be disposed on the first semiconductor layer 123. The second insulation layer 104 may be formed of the same material as that of the first insulation layer 103, but the embodiments of the present disclosure are not limited thereto. The second insulation layer 104 may prevent a short circuit between the first semiconductor layer 123 and other components of the first thin film transistor 120. The second insulation layer 104 may be a gate insulation layer, but is not limited thereto.

The first gate electrode 122 may be disposed on the second insulation layer 104. The first gate electrode 122 may be disposed on the second insulation layer 104 to overlap the channel region of the first semiconductor layer 123. The first gate electrode 122 may be a single layer or a multi-layer formed of one among molybdenum (Mo), copper (Cu), titanium (Ti), aluminum (Al), Chrome (Cr), gold (Au), nickel (Ni), neodymium (Nd), and or a compound of any of these materials, but the embodiments of the present disclosure are not limited thereto. The first gate electrode 122 may be disposed together with the gate line, but the embodiments of the present disclosure are not limited thereto. Hereinafter, a conductive layer at or in which the first gate electrode 122 is disposed may be referred to as a second conductive layer. A storage electrode 140 may be disposed with spacing apart from the first thin film transistor 120. The storage electrode 140 may include a first storage electrode 141, a second storage electrode 142, and a third storage electrode 143.

The first storage electrode 141 may be formed of the same material as that of the first gate electrode 122, disposed on the same layer on which the first gate electrode 122 is disposed, and disposed at the second conductive layer, but the embodiments of the present disclosure are not limited thereto.

A third insulation layer 105 may be disposed on the first gate electrode 122 and the first storage electrode 141. The third insulation layer 105 may be formed of the same material as that of the first insulation layer 103 or the second insulation layer 104, but the embodiments of the present disclosure are not limited thereto. The third insulation layer 105 may be an interlayer insulation layer, but is not limited thereto.

The second storage electrode 142 may be disposed on the third insulation layer 105. With the third insulation layer 105 between the first storage electrode 141 and the second storage electrode 142 functioning as a dielectric, a capacitance may be formed. The second storage electrode 142 may be formed of the same material as that of the first storage electrode 141, but the embodiments of the present disclosure are not limited thereto. Hereinafter, a conductive layer at or in which the second storage electrode 142 is disposed may be referred to as a third conductive layer.

A fourth insulation layer 106 may be disposed on the third conductive layer. The fourth insulation layer 106 may be formed of the same material as that of the first insulation layer 103, the second insulation layer 104, or the third insulation layer 105, but the embodiments of the present disclosure are not limited thereto.

The first source electrode 121 and the first drain electrode 124 may be disposed on the fourth insulation layer 105.

The first source electrode 121 and the first drain electrode 124 may be electrically connected to the first semiconductor layer 123 through a contact hole. The first source electrode 121 and the first drain electrode 124 may be formed of a metal material. For example, the first source electrode 121 and the first drain electrode 124 may be a single layer or a multi-layer formed of one among molybdenum (Mo), aluminum (Al), Chrome (Cr), gold (Au), titanium (Ti), nickel (Ni), neodymium (Nd), and copper (Cu), or an alloy of any of these materials, but the embodiments of the present disclosure are not limited thereto. Hereinafter, a conductive layer at or in which the first source electrode 121 and the first drain electrode 124 are disposed may be referred to as a fourth conductive layer.

The first source electrode 121 and the first drain electrode 124 may be disposed together with a data line. For example, the data line may be formed of the same material as that of the first source electrode 121 and the first drain electrode 124 and may be disposed on the same layer on which the first source electrode 121 and the first drain electrode 124 are disposed, but the embodiments of the present disclosure are not limited thereto. The third storage electrode 143 of the storage electrode 140 may be further disposed at or in the fourth conductive layer. The third storage electrode 143 may be electrically connected to the second storage electrode 142 through a contact hole. The third storage electrode 143 may be omitted.

A first protection layer 111 may be disposed on the fourth conductive layer. The first protection layer 111 may flatten an upper portion of the first thin film transistor 120, and protect the first thin film transistor 120. The first protection layer 111 may be formed of an organic material. For example, the first protection layer 111 may be formed of an organic material including an acrylic resin, an epoxy resin, a phenolic resin, a polyamide resin, or a polyimide resin, but the embodiments of the present disclosure are not limited thereto.

A second protection layer 112 may be disposed on the first protection layer 111. The second protection layer 112 may be formed of the same material as that of the first protection layer 111, but the embodiments of the present disclosure are not limited thereto.

A connection electrode 145 may be disposed between the first protection layer 111 and the second protection layer 112. Hereinafter, a conductive layer at or in which the connection electrode 145 is disposed may be referred to as a fifth conductive layer.

The connection electrode 145 may electrically connect the first thin film transistor 120 and the light emitting part 150. The connection electrode 145 may be formed of the same material as those of the first source electrode 121 and the first drain electrode 124, but the embodiments of the present disclosure are not limited thereto.

The connection electrode 145 may be a single layer or a multi-layer formed of one among molybdenum (Mo), aluminum (Al), Chrome (Cr), gold (Au), titanium (Ti), nickel (Ni), neodymium (Nd), and copper (Cu), or an alloy of any of these materials, but the embodiments of the present disclosure are not limited thereto.

The light emitting part 150 may be disposed on the second protection layer 112. The light emitting part 150 may include the anode electrode 151, an organic layer 152, and the cathode electrode 153.

The anode electrode 151 may be disposed on the second protection layer 112. The anode electrode 151 may be electrically connected to the first thin film transistor 120 through a contact hole formed on the second protection layer 112. The anode electrode 151 may be a reflective electrode which reflects light, but the embodiments of the present disclosure are not limited thereto. The anode electrode 151 may include a metal material having a high reflectance such as s a stacked structure (Ti/Al/Ti) of Al and Ti, a stacked structure (ITO/Al/ITO) of Al and ITO, or an APC alloy, and may be formed as a single layer or a multi-layer, but the embodiments of the present disclosure are not limited thereto. Hereinafter, a conductive layer at or in which the anode electrode 151 is disposed may be referred to as a sixth conductive layer.

The organic layer 152 may be disposed on the anode electrode 151. The organic layer 152 may include one or more emission structure (or light emitting element or element) which are stacked on the anode electrode 151 in the order or reverse order of a hole transport layer, and an electron transport layer. For example, the hole transport layer may include a hole transport layer, a hole injection layer, an electron blocking layer, or a P-type charge generation layer, etc., but the embodiments of the present disclosure are not limited thereto. For example, the electron transport layer may include an electron transport layer, an electron injection layer, a hole blocking layer, or a N-type charge generation layer, etc., but the embodiments of the present disclosure are not limited thereto. The organic layer 152 may be an organic light emitting layer, an inorganic light emitting layer, and a quantum-dot light emitting layer, a micro light emitting diode, or a micro/mini light-emitting diode etc., but the embodiments of the present disclosure are not limited thereto. For example, the organic layer 152 of the display panel 100 according to an example embodiment of the present disclosure may include an organic light emitting layer. The organic layer 152 may include a red light emitting layer, a green light emitting layer, and a blue light emitting layer. The organic layer 152 may further include a while light emitting layer, but the embodiments of the present disclosure are not limited thereto.

The cathode electrode 153 may be disposed on the organic layer 152. The cathode electrode 153 may be a transparent electrode transmitting light, but the embodiments of the present disclosure are not limited thereto. For example, the cathode electrode 153 may include a transparent conductive material such as indium tin oxide (ITO) or indium zinc oxide (IZO) or a metal through which visible light is transmitted.

The bank 154 may be disposed to expose the anode electrode 151. The bank 154 may be disposed to define an opening of a pixel (or a light emitting region), and to cover an edge of the anode electrode 151.

The pixel may include a plurality of subpixels SP. Each of the pixels may include a red light emitting region, a green light emitting region, and a blue light emitting region which correspond to the plurality of subpixels SP. As another example, the pixel may further include a white light emitting region, but is not limited thereto. The bank 154 may be formed of an organic material such as a material including a black pigment etc., benzocyclobutene resin, polyimide resin, acrylic resin, or photosensitive polymer, but is not limited thereto. If the bank 154 is formed of a material including a black pigment or a black dye, the bank 154 may be a black bank. If the bank 154 is configured with a material including a black pigment or a black dye, it becomes possible to block light from the outside, or block light reflected from the outside; therefore, the brightness of the display device may be further improved.

The encapsulation layer 170 may be disposed on the bank 154 or the light emitting part 150. The encapsulation layer 170 may include one or more insulation layers. For example, the encapsulation layer 170 may include a first encapsulation layer 171, a second encapsulation layer on the first encapsulation layer 171, and a third encapsulation layer 173 on the second encapsulation layer 172. The encapsulation layer 170 may include one or more inorganic material layers or one or more organic material layers. For example, the first encapsulation layer 171 and the third encapsulation layer 173 may include an inorganic material, and the second encapsulation layer 172 may include an organic material, but the embodiments of the present disclosure are not limited thereto.

Referring back to FIGS. 5, 7 to 10, the source film SF may include a first source film SF1, and a second source film SF2 adjacent to the first source film SF1. The first source film SF1 may be disposed on (or at) one side in the first direction DR1 of the second source film SF2, and the first source film SF1 may be disposed on the most one end in the first direction DR1 among the plurality of source films SF. Each of the source films SF1 and SF2 may be electrically connected to a plurality of pads in the non-display area on an upper side of the display area DA. Each of the source films SF1 and SF2 may include a plurality of lead terminals for allowing the source films SF1 or SF2 to be electrically connected to the plurality of pads.

The plurality of pads electrically connected to the second source film SF2 may include a main ground voltage pad PAD_VSS1 disposed adjacent to the first source film SF1, and disposed on the most one end in the first direction DR1. The main ground voltage pad PAD_VSS1 may be disposed on the most another end in the first direction DR1 among the pads electrically connected to the second source film SF2.

The plurality of pads electrically connected to the first source film SF1 may include the main ground voltage pad PAD_VSS1 disposed adjacent to the second source film SF2 and disposed on the most another end in the first direction DR1, the gate signal supply pad PAD_LOG disposed on the most one end in the first direction DR1, and the additional ground voltage supply pad PAD_VSS2 disposed between the main ground voltage pad PAD_VSS1 and the gate signal supply pad PAD_LOG.

Each of the main ground voltage pad PAD_VSS1, the gate signal supply pad PAD_LOG, and the additional ground voltage supply pad PAD_VSS2 may be configured with a plurality of pad parts, which are alternately stacked with each other, but is not limited thereto. For example, each of the main ground voltage pad PAD_VSS1, the gate signal supply pad PAD_LOG, and the additional ground voltage supply pad PAD_VSS2 may include a first pad part PAD1, and a second pad part PAD2. The first pad part PAD1 and the second pad part PAD2 may be disposed at or in each different conductive layer. The second pad part PAD2 may be disposed on the first pad part PAD1. The ground voltage (refer to EVSS in FIG. 3) is applied to the main ground voltage pad PAD_VSS1, and the additional ground voltage supply pad PAD_VSS2, and the gate control signal may be applied to the gate signal supply pad PAD_LOG. The first pad part PAD1 may be disposed at or in the second conductive layer. The second pad part PAD2 may be disposed at or in the sixth conductive layer, but is not limited thereto.

The second pad part PAD2 of the main ground voltage pad PAD_VSS1 electrically connected to each of the first and the second source films SF1 and SF2 may be electrically connected to a main ground voltage lead terminal of each of the first and the second source films SF1 and SF2. The second pad part PAD2 of the main ground voltage pad PAD_VSS1 electrically connected to each of the first and the second source films SF1 and SF2 may be electrically connected to the first pad part PAD1 through a pad contact hole CNT_P. The first pad part PAD1 electrically connected to each of the first and the second source films SF1 and SF2 may extend toward the other side of the second direction DR2. A portion extending toward the other side of the second direction DR2 of the first pad part PAD1 electrically connected to each of the first and the second source films SF1 and SF2 may not overlap the first and the second source films SF1 and SF2, respectively.

A first ground voltage electrode ED_VSS1 may be disposed between the first and the second source films SF1 and SF2 and the display area DA, and between the first source film SF1 and the second source film SF2. The first ground voltage electrode ED_VSS1 may include a first ground voltage electrode part ED_VSS1a, a second ground voltage electrode part ED_VSS1b on the first ground voltage electrode part ED_VSS1a, and a third ground voltage electrode part ED_VSS1c on the second ground voltage electrode part ED_VSS1b. The first ground voltage electrode part ED_VSS1a may be disposed at or in the first conductive layer, the second ground voltage electrode part ED_VSS1b may be disposed at or in the second conductive layer, and the third ground voltage electrode part ED_VSS1c may be disposed at or in the sixth conductive layer, but are not limited thereto.

The first pad parts PAD1 of each of the first and the second source films SF1 and SF2 may be electrically connected to the second ground voltage electrode part ED_VSS1b. The first pad parts PAD1 of each of the first and the second source films SF1 and SF2 may be disposed on the same layer as that of the second ground voltage electrode part ED_VSS1b, respectively. The first pad parts PAD1 of each of the first and the second source films SF1 and SF2 may be integrally formed with the second ground voltage electrode part ED_VSS1b, respectively. The second ground voltage electrode part ED_VSS1b may partially overlap the cathode electrode 153.

The first ground voltage electrode part ED_VSS1a may overlap the second ground voltage electrode part ED_VSS1b. The first ground voltage electrode part ED_VSS1a may be electrically connected to the second ground voltage electrode part ED_VSS1b. The first ground voltage electrode part ED_VSS1a may partially overlap the cathode electrode 153. The second ground voltage electrode part ED_VSS1b may be electrically connected to the first ground voltage electrode part ED_VSS1a through a first contact hole CNT1. The second ground voltage electrode part ED_VSS1b may decrease a resistance, by being electrically connected to the first ground voltage electrode part ED_VSS1a through the first contact hole CNT1.

The third ground voltage electrode part ED_VSS1c may overlap the first and the second ground voltage electrode parts ED_VSS1a and ED_VSS1b. The third ground voltage electrode part ED_VSS1c may be electrically connected to the first and the second ground voltage electrode parts ED_VSS1a and ED_VSS1b. The third ground voltage electrode part ED_VSS1c may be electrically connected to the second ground voltage electrode part ED_VSS1b through a contact hole. The third ground voltage electrode part ED_VSS1c may overlap the cathode electrode 153. The third ground voltage electrode part ED_VSS1c may be electrically connected to the cathode electrode 153. The third ground voltage electrode part ED_VSS1c may be electrically connected to the cathode electrode 153 through a third contact hole CNT3. The third contact hole CNT3 may be the same as the first contact area CC1 described above, but is not limited thereto. The cathode electrode 153 may be supplied with the ground voltage through the first ground voltage electrode part ED_VSS1.

The second pad part PAD2 of the gate signal supply pad PAD_LOG electrically connected to the first source film SF1 may be electrically connected to the gate signal supply lead terminal of the first source film SF1. The second pad part PAD2 of the gate signal supply pad PAD_LOG electrically connected to the first source film SF1 may be electrically connected to the first pad part PAD1 through the pad contact hole CNT_P. The first pad part PAD1 electrically connected to the first source film SF1 may extend toward the other side of the second direction DR2. A portion extending toward the other side of the second direction DR2 of the first pad part PAD1 electrically connected to the first source film may not overlap the first source film SF1.

The gate signal supply pad PAD_LOG may be electrically connected to the gate driving circuit 200 through a gate signal supply line LN_LOG. The gate signal supply line LN_LOG may include a first gate signal supply line LN_LOG1 and a second gate signal supply line LN_LOG2. The first gate signal supply line LN_LOG1 may be electrically connected to the first pad part PAD1 of the gate signal supply pad PAD_LOG, and may be disposed on the same layer as that of the first pad part PAD1 of the gate signal supply pad PAD_LOG. The first gate signal supply line LN_LOG1 may be disposed at or in the second conductive layer. The first gate signal supply line LN_LOG1 may be integrally formed with the first pad part PAD1 of the gate signal supply pad PAD_LOG.

The second gate signal supply line LN_LOG2 may be electrically connected to the first gate signal supply line LN_LOG1. The second gate signal supply line LN_LOG2 may be electrically connected to the first gate signal supply line LN_LOG1 through a fourth contact hole CNT4. The second gate signal supply line LN_LOG2 may be disposed at or in the first conductive layer. The second gate signal supply line LN_LOG2 may extend toward the other side of the second direction DR2, be bent and extend toward one side of the first direction DR1, extend toward the other side of the second direction DR2 again and may be electrically connected to the gate driving circuit 200.

The second pad part PAD2 of the additional ground voltage supply pad PAD_VSS2 electrically connected to the first source film SF1 may be electrically connected to the additional ground voltage supply lead terminal of the first source film SF1. The second pad part PAD2 of the additional ground voltage supply pad PAD_VSS2 electrically connected to the first source film SF1 may be electrically connected to the first pad part PAD1 through the pad contact hole CNT_P. The first pad part PAD1 electrically connected to the first source film SF1 may extend toward the other side of the second direction DR2. A portion extending toward the other side of the second direction DR2 of the first pad part PAD1 electrically connected to the first source film SF1 may not overlap the first source film SF1.

The additional ground voltage supply pad PAD_VSS2 may be electrically connected to the gate driving circuit 200 through the additional ground voltage supply line LN_VSS2. The additional ground voltage supply line LN_VSS2 may include a first additional ground voltage supply line LN_VSS2a, a second additional ground voltage supply line LN_VSS2b, and a third additional ground voltage supply line LN_VSS2c.

The first additional ground voltage supply line LN_VSS2a may be electrically connected to the first pad part PAD1 of the additional ground voltage supply pad PAD_VSS2, and disposed on the same layer as that of the first pad part PAD1 of the additional ground voltage supply pad PAD_VSS2. The first additional ground voltage supply line LN_VSS2a may be disposed at or in the second conductive layer. The first additional ground voltage supply line LN_VSS2a may be integrally formed with the first pad part PAD1 of the additional ground voltage supply pad PAD_VSS2.

The second additional ground voltage supply line LN_VSS2b may be electrically connected to the first additional ground voltage supply line LN_VSS2a. The second additional ground voltage supply line LN_VSS2b may be electrically connected to the first additional ground voltage supply line LN_VSS2a through a fifth contact hole CNT5. The second additional ground voltage supply line LN_VSS2b may be disposed at or in the first conductive layer. The second additional ground voltage supply line LN_VSS2b may extend toward the other side of the second direction DR2. The third additional ground voltage supply line LN_VSS2c may be electrically connected to the second additional ground voltage supply line LN_VSS2b. The third additional ground voltage supply line LN_VSS2c may be electrically connected to the second additional ground voltage supply line LN_VSS2b through a sixth contact hole CNT6. The third additional ground voltage supply line LN_VSS2c may extend in the first direction DR1. The additional ground voltage supply line LN_VSS2 may electrically connect the additional ground voltage supply pad PAD_VSS2 and a second ground voltage electrode ED_VSS2 to each other. The second ground voltage electrode ED_VSS2 may be the trench pixel electrode.

Meanwhile, since the second ground voltage electrode ED_VSS2 is disposed in the trench area 800, the second ground voltage electrode ED_VSS2 is disposed outside the gate driving circuit 200, and the second ground voltage supply pad PAD_VSS2 is disposed on or at an inner side of the gate signal supply pad PAD_LOG, the second ground voltage supply line LN_VSS2 inevitably intersecting the gate signal supply line LN_LOG. In more detail, the second gate signal supply line LN_LOG2 and the second ground voltage supply line LN_VSS3 may intersect each other. Therefore, in the area in which the second ground voltage supply line LN_VSS2 and the second gate signal supply line LN_LOG2, disposed in or at the first conductive layer, intersect, the second ground voltage supply line LN_VSS2 may jump the second gate signal supply line LN_LOG2 so as to prevent a short circuit with the second gate signal supply line LN_LOG2 in advance. For example, the third additional ground voltage supply line LN_VSS2c disposed at or in the sixth conductive layer may be a jumping electrode. The second ground voltage supply line LN_VSS2 may extend to the second ground voltage electrode ED_VSS2 through the third additional ground voltage supply line LN_VSS2c disposed on a layer different from a layer on which the second gate signal supply line LN_LOG2 is disposed, so as to prevent a short circuit with the second gate signal supply line LN_LOG2.

In some example embodiments, the third additional ground voltage supply line LN_VSS2c may be disposed at or in the second conductive layer. Hereinafter, it will be described focusing on a case in which the third additional ground voltage supply line LN_VSS2c is disposed at or in the sixth conductive layer.

The third additional ground voltage supply line LN_VSS2c may be electrically connected to the additional ground voltage electrode ED_VSS2. The third additional ground voltage supply line LN_VSS2c may be disposed on the same layer on which the additional ground voltage electrode ED_VSS2 is disposed, and may be integrally formed with the additional ground voltage electrode ED_VSS2.

The additional ground voltage electrode ED_VSS2 may be disposed in the trench area 800, may overlap the cathode electrode 153, and may be electrically connected to the cathode electrode 153. A contact area in which the additional ground voltage electrode ED_VSS2 and the cathode electrode 153 contact each other may be referred to as the second contact area CC2. The trench area 800 and the additional ground voltage electrode ED_VSS2 may be disposed in the non-display area NDA on right, lower and left sides of the display area DA. Therefore, in the non-display area NDA on an upper portion of the display area DA on which the first contact area CC1 is disposed, not only a contact between the third ground voltage electrode part ED_VSS1c and the cathode electrode 153 is established (or is made), but also a contact between the additional ground voltage electrode ED_VSS2 and the cathode electrode 153 is established; therefore, concentration of the heat and the current only in the first contact area CC1 may be prevented.

As illustrated in FIG. 7, the third insulation layer 105, and the fourth insulation layer 106 may expose the first pad part PAD1, without overlapping the first pad part PAD1, but are not limited thereto.

The bank 154 may expose the second pad part PAD2. The bank 154 may cover the edge of the second pad part PAD2, but is not limited thereto. A side surface of the bank 154 may overlap a side surface of the organic layer 152, and a side surface of the encapsulation layer 170, but is not limited thereto.

The first source film SF1 may be disposed over the second pad part PAD2. The first source film SF1 may include a lead terminal. For example, a lead terminal illustrated in FIG. 7 may be a main ground voltage supply lead terminal. An anisotropic conductive film (ACF) may be disposed between the lead terminal and the second pad part PAD2. The anisotropic conductive film (ACF) may include conductive balls CB and a resin SR in which the conductive ball CB are distributed. The conductive balls CB may serve to electrically connect the lead terminal and the second pad part PAD2 to each other.

As illustrated in FIG. 8, the second gate signal supply line LN_LOG2 may be disposed at or in a conductive layer that is different from a layer on which the third additional ground voltage supply line LN_VSS2c is disposed. The third additional ground voltage supply line LN_VSS2c may overlap the cathode electrode 153.

As illustrated in FIGS. 9 and 10, the substrate 101, the second insulation layer 104 on the substrate 101, the additional ground voltage electrode ED_VSS2 on the second insulation layer 104, and the cathode electrode 153 may be disposed in the trench area 800. In the trench area 800, the buffer layer 102, the first insulation layer 103, the third insulation layer 105, the fourth insulation layer 106, the first protection layer 111, the second protection layer 112, the bank 154, and the encapsulation layer 170 may not be disposed, but are not limited thereto. The additional ground voltage electrode ED_VSS2 may directly contact the second insulation layer 104, and the cathode electrode 153 may directly contact the additional ground voltage electrode ED_VSS2, because the buffer layer 102, the first insulation layer 103, the third insulation layer 105, the fourth insulation layer 106, the first protection layer 111, the second protection layer 112, the bank 154, are not disposed in the trench area 800.

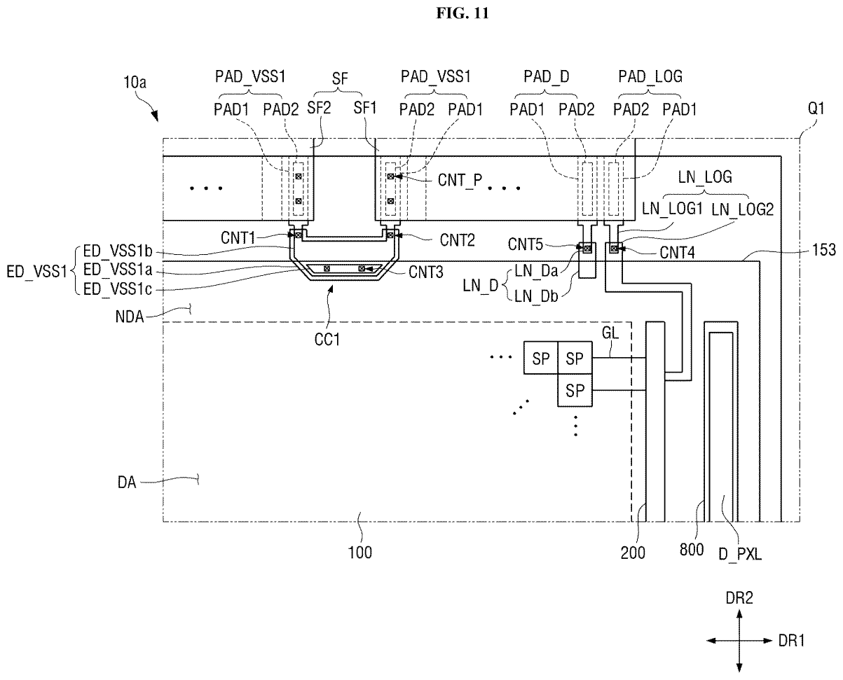

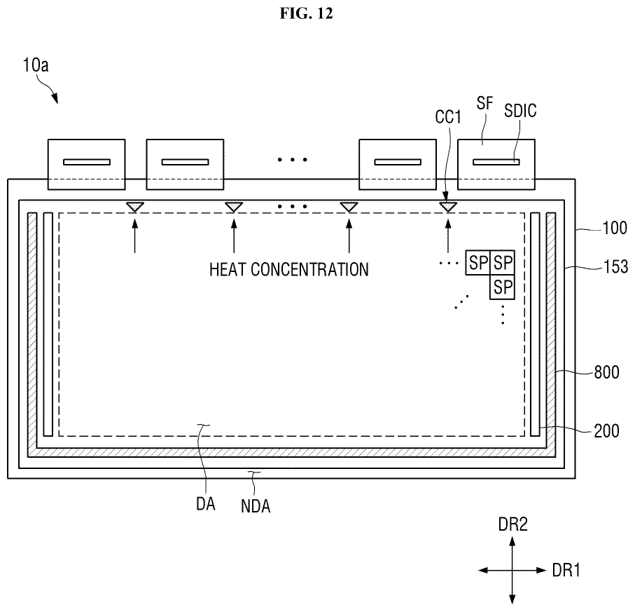

FIG. 11 is a cross-sectional view of a display device according to a comparative embodiment. FIG. 12 is a schematic view illustrating concentration of the heat in the display device according to the comparative embodiment.

Referring to FIGS. 11 and 12, the display panel 100 of the display device 10a according to the comparative embodiment may include a dummy pad PAD_D. The dummy pad PAD_D according to FIGS. 11 and 12 may be disposed instead of the additional ground voltage supply pad PAD_VSS2 according to FIG. 5. That is, the display device 10a according to the comparative embodiment may not include the additional ground voltage supply pad PAD_VSS2. The electric signal may not be applied to the dummy pad PAD_D at all from the source film SF.

The dummy pad PAD_D may include the first pad part PAD1 and the second pad part PAD2 described with reference to FIG. 5. The first pad part PAD1 and the second pad part PAD2 have been described with reference to FIG. 5; therefore, redundant description will be omitted.

The dummy pad PAD_D may be connected to dummy lines LN_Da and LN_Db. The first dummy line LN_Da may be disposed on the same layer as a layer on which the first pad part PAD1 is disposed, and may be electrically connected to the first pad part PAD1. The second dummy line LN_Db may be connected to the first dummy line LN_Da through the fifth contact hole CNT5. A dummy pixel electrode D_PXL may be disposed in the trench area 800. The dummy pixel electrode D_PXL and the dummy lines LN_D may not be electrically connected to each other.

As illustrated in FIG. 12, the display device 10a according to the comparative embodiment may not include the second contact area (refer to CC2 in FIG. 5), but may include only the first contact area CC1. By doing so, in the first contact area CC1, not only the heat may be concentrated, but also the current may be concentrated.

However, as described with reference to FIGS. 5 to 10, in case of the display device 10 according to the first example embodiment, by supplying the ground voltage to the dummy pad PAD_D corresponding to the first source film SF in FIG. 11 (from the dummy pad PAD_D to the additional ground voltage supply pad(PAD_VSS2 in FIG. 5)) and by electrically connecting the additional ground voltage supply pad PAD_VSS2 to the dummy pixel electrode D_PXL (if connected to the additional ground voltage supply pad PAD_VSS2, to the second ground voltage electrode ED_VSS2), the second contact area CC2 may be secured more. With this configuration, a fault in the display device may be prevented by distributing concentration of the heat and the current generated in the first contact area CC1.

Hereinafter, the display devices according to other example embodiments will be described. Detailed description about the same or similar components which have been described with reference to FIGS. 1 to 12 will be omitted or the redundant description thereof will be omitted.

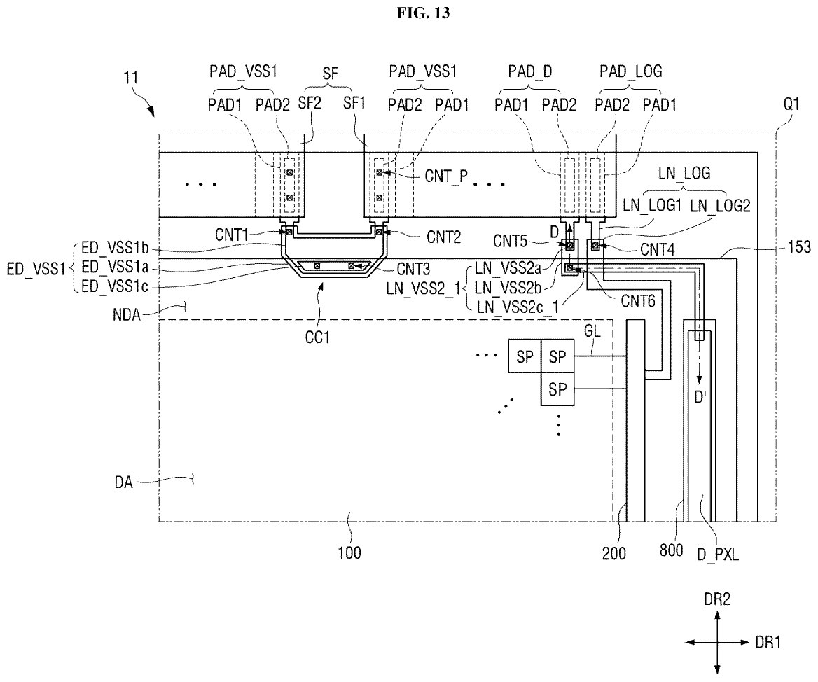

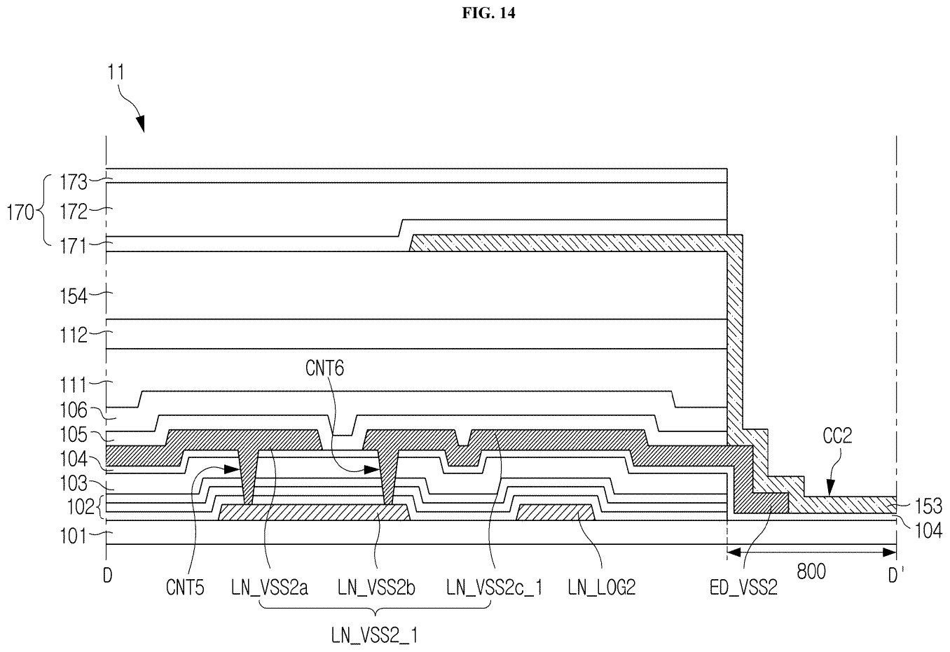

FIG. 13 is a plan view of the display device according to a second example embodiment. FIG. 14 is an example of a cross-sectional view taken along D-D′ line of FIG. 13.

Referring to FIGS. 13 and 14, because a display device 11 according to the second example embodiment includes an additional ground voltage supply line LN_VSS2_1, the display device 11 according to the second example embodiment is different from the display device 10 according to the FIGS. 5 to 10.

The additional ground voltage supply line LN_VSS2_1 may include a third additional ground voltage supply line LN_VSS2c_1. The third additional ground voltage supply line LN_VSS2c_1 may be disposed at or in the second conductive layer.

Since the second ground voltage electrode ED_VSS2 is disposed in the trench area 800, the second ground voltage electrode ED_VSS2 is disposed outside the gate driving circuit 200, and the second ground voltage supply pad PAD_VSS2 is disposed on an inner side of the gate signal supply pad PAD_LOG, a second ground voltage supply line LN_VSS2_1 inevitably intersecting the gate signal supply line LN_LOG. In more detail, the second gate signal supply line LN_LOG2 and the second ground voltage supply line LN_VSS2_1 may intersect. Therefore, in order to prevent the short circuit with the second gate signal supply line LN_LOG2, the second ground voltage supply line LN_VSS2_1 may jump the second gate signal supply line LN_LOG in an area in which the second ground voltage supply line LN_VSS2_1 and the second gate signal supply line LN_LOG2, disposed at or in the first conductive layer, intersect. For example, the third additional ground voltage supply line LN_VSS2c_1 disposed at or in the second conductive layer may be a jumping electrode. The second ground voltage supply line LN_VSS2_1 may extend to the second ground voltage electrode ED_VSS2 through the third additional ground voltage supply line LN_VSS2c_1 disposed on a layer different from a layer on which the second gate signal supply line LN_LOG2 is disposed, so as to prevent a short circuit between the second ground voltage supply line LN_VSS2_1 and the second gate signal supply line LN_LOG2.

In the present example embodiment, the additional ground voltage electrode ED_VSS2 may be disposed in the trench area 800, overlap the cathode electrode 153, and be electrically connected to the cathode electrode 153. The trench area 800 and the additional ground voltage electrode ED_VSS2 may be disposed in the non-display area NDA on left, lower, and right sides of the display area DA. Therefore, in the non-display area NDA on an upper portion of the display area DA on which the first contact area CC1 is disposed, not only a contact between the third ground voltage electrode part ED_VSS1c and the cathode electrode 153 is established, but also a contact between the additional ground voltage electrode ED_VSS2 and the cathode electrode 153 is established in the second contact area CC2; therefore, concentration of the heat and the current only in the first contact area CC1 may be prevented.

As illustrated in FIG. 14, in the trench area 800, the substrate 101, the second insulation layer 104 on the substrate 101, the third additional ground voltage supply line LN_VSS2c_1 on the second insulation layer 104, the additional ground voltage electrode ED_VSS2 on the third additional ground voltage supply line LN_VSS2c_1, and the cathode electrode 153 may be disposed. In the trench area 800, the buffer layer 102, the first insulation layer 103, the third insulation layer 105, the fourth insulation layer 106, the first protection layer 111, the second protection layer 112, the bank 154, and the encapsulation layer 170 may not be disposed, but the embodiments are not limited thereto. Since the buffer layer 102, the first insulation layer 103, the third insulation layer 105, the fourth insulation layer 106, the first protection layer 111, the second protection layer 112, and the bank 154 are not disposed in the trench area 800, the additional ground voltage electrode ED_VSS2 may directly contact the third additional ground voltage supply line LN_VSS2c_1, and the cathode electrode 153 may directly contact the additional ground voltage electrode ED_VSS2.

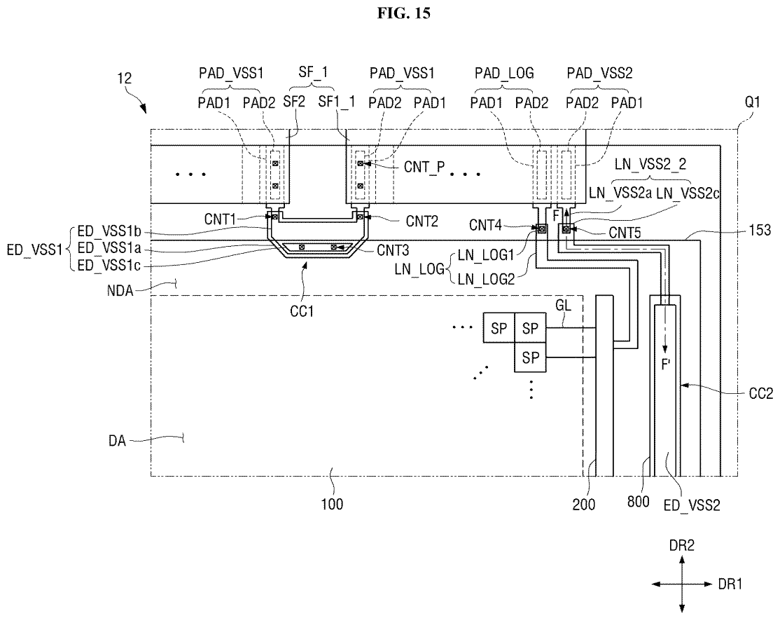

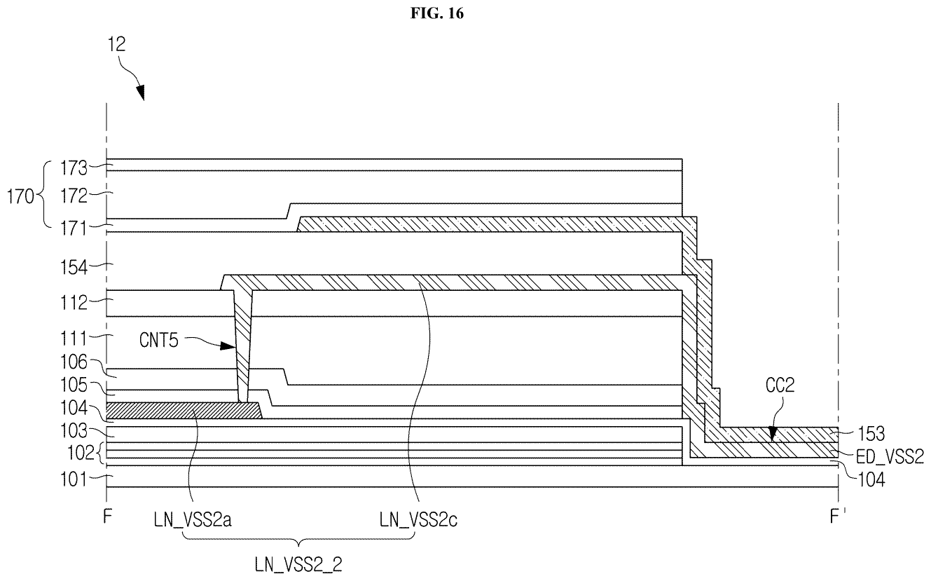

FIG. 15 is a plan view of a display device according to a third example embodiment. FIG. 16 is an example of a cross-sectional view taken along F-F′ line of FIG. 15.

Referring to FIGS. 15 and 16, the source film SF_1 of a display device 12 according to a third example embodiment may include a first source film SF1_1 and the second source film SF2. The first source film SF1_1 may be disposed on one side of the second source film SF2 in the first direction DR1. A position of the first source film SF1_1 may be the same as a position of the first source film SF1 illustrated in FIG. 5.

As illustrated in FIGS. 15 and 16, positions of the gate signal supply pad PAD_LOG and the additional ground voltage supply pad PAD_VSS2 electrically connected to the first source film SF1_1 may be opposite to positions of the gate signal supply pad PAD_LOG and the additional ground voltage supply pad PAD_VSS2 according to FIG. 5. That is, the additional ground voltage supply pad PAD_VSS2 according to FIG. 15 may be disposed on (or at) one side of the gate signal supply pad PAD_LOG in the first direction DR1. Since the additional ground voltage supply pad PAD_VSS2 is disposed outside the gate signal supply pad PAD_LOG and the trench area 800 is disposed outside the gate driving circuit 200, the additional ground voltage supply line LN_VSS2_2 may be disposed outside the gate signal supply line LN_LOG. Therefore, the additional ground voltage supply line LN_VSS2_2 may not intersect the gate signal supply line LN_LOG. The additional ground voltage supply line LN_VSS2_2 may include the first additional ground voltage supply line LN_VSS2a and the third additional ground voltage supply line LN_VSS2c. The third additional ground voltage supply line LN_VSS2c may be electrically connected to the first additional ground voltage supply line LN_VSS2a through the fifth contact hole CNT5. The third additional ground voltage supply line LN_VSS2c may extend toward the other side of the second direction DR2, be bent toward one side in the first direction DR1, and extend again toward the other side of the second direction DR2, thereby being electrically connected to the second ground voltage electrode ED_VSS2. The third additional ground voltage supply line LN_VSS2c may be disposed at or in the sixth conductive layer, and may be disposed on the same layer as a layer on which the second ground voltage electrode ED_VSS2 is disposed. The third additional ground voltage supply line LN_VSS2c may be integrally formed with the second ground voltage electrode ED_VSS2.

In some example embodiments, the third additional ground voltage supply line LN_VSS2c may be disposed at or in the first conductive layer or the second conductive layer.

As illustrated in FIG. 16, the substrate 101, the second insulation layer 104 on the substrate 101, the additional ground voltage electrode ED_VSS2 on the second insulation layer 104, and the cathode electrode 153 may be disposed in the trench area 800. In the trench area 800, the buffer layer 102, the first insulation layer 103, the third insulation layer 105, the fourth insulation layer 106, the first protection layer 111, the second protection layer 112, the bank 154, and the encapsulation layer 170 may not be disposed, but the embodiments are not limited thereto. Since the buffer layer 102, the first insulation layer 103, the third insulation layer 105, the fourth insulation layer 106, the first protection layer 111, the second protection layer 112, and the bank 154 are not disposed in the trench area 800, the additional ground voltage electrode ED_VSS2 may directly contact the second insulation layer 104, and the cathode electrode 153 may directly contact the additional ground voltage electrode ED_VSS2.

In the present example embodiment, the additional ground voltage electrode ED_VSS2 may be disposed in the trench area 800, may overlap the cathode electrode 153, and may be electrically connected to the cathode electrode 153. The trench area 800 and the additional ground voltage electrode ED_VSS2 may be disposed in the non-display area NDA on right, lower, and left sides of the display area DA. Therefore, in the non-display area NDA on an upper portion of the display area DA on which the first contact area CC1 is disposed, not only a contact between the third ground voltage electrode part ED_VSS1c and the cathode electrode 153 is established, but also a contact between the additional ground voltage electrode ED_VSS2 and the cathode electrode 153 is established in the second contact area CC2; therefore, concentration of the heat and the current only in the first contact area CC1 may be prevented.

In one or more examples, an element may include a plurality of elements. In an example, a voltage supply line may include a plurality of voltage supply lines. In an example, a signal supply line may include a plurality of signal supply lines. In an example, a pad may include a plurality of pads. In an example, an electrode may include a plurality of electrodes.

In one or more examples, an element(s) (e.g., a voltage supply line, a signal supply line, an electrode, a pad, or a pad part) may be disposed at or in a conductive layer. In an example, such a conductive layer may comprise the element(s). In an example, the element(s) may be formed or patterned using such a conductive layer. In an example, such a conductive layer may be deposited and then patterned to form the element(s).

Various examples and aspects of the present disclosure are described below. These are provided as examples, and do not limit the scope of the present disclosure.

One example embodiment is a display device, including: a display panel comprising a display area; a non-display area disposed outside or around the display area; and a first source film and a second source film attached to or on the non-display area, and the display panel may include: a substrate; a first ground voltage supply pad disposed on the substrate and for being electrically connected to the first source film; a trench pixel electrode for being electrically connected to the first ground voltage supply pad and disposed in a trench area of the non-display area; and a cathode electrode on the substrate, and the cathode electrode may be electrically connected to the trench pixel electrode in the trench area.

According to various example embodiments of the present disclosure, the display panel may further include: a gate driving circuit between the trench area and the display area; and a gate signal supply pad disposed at one side of the first ground voltage supply pad and for being electrically connected to the first source film, and the gate signal supply pad may be electrically connected to the gate driving circuit.

According to various example embodiments of the present disclosure, the display panel may further include: a first ground voltage supply line that connects the first ground voltage supply pad and the trench pixel electrode to each other; and a gate signal supply line that connects the gate signal supply pad and the gate driving circuit to each other, and the first ground voltage supply line and the gate signal supply line may intersect each other on a plane.

According to various example embodiments of the present disclosure, the first ground voltage supply line may be disposed on a layer which is different from a layer on which the gate signal supply line is disposed.

According to various example embodiments of the present disclosure, the gate signal supply line may include: a first gate signal supply line connected to the gate signal supply pad; and a second gate signal supply line that connects the first gate signal supply line and the gate driving circuit to each other, and the second gate signal supply line may be disposed at a first conductive layer, and the first gate signal supply line may be disposed at a second conductive layer that is on the first conductive layer.

According to various example embodiments of the present disclosure, the trench pixel electrode may be disposed at a third conductive layer that is on the second conductive layer, and the cathode electrode may be disposed at the third conductive layer.

According to various example embodiments of the present disclosure, the first ground voltage supply line may include: a first-first ground voltage supply line connected to the first ground voltage supply pad; a first-second ground voltage supply line connected to the first-first ground voltage supply line; and a first-third ground voltage supply line connected to the first-second ground voltage supply line and the trench pixel electrode, and the first-first ground voltage supply line may be disposed at the second conductive layer, the first-second ground voltage supply line may be disposed at the first conductive layer, and the first-third ground voltage supply line may be disposed at the third conductive layer.

According to various example embodiments of the present disclosure, the first-third ground voltage supply line and the second gate signal supply line may intersect each other.

According to various example embodiments of the present disclosure, the first ground voltage supply line may include: a first-first ground voltage supply line connected to the first ground voltage supply pad; a first-second ground voltage supply line connected to the first-first ground voltage supply line; and a first-third ground voltage supply line connected to the first-second ground voltage supply line and the trench pixel electrode, and the first-first ground voltage supply line may be disposed at the second conductive layer, the first-second ground voltage supply line may be disposed at the first conductive layer, and the first-third ground voltage supply line may be disposed at the second conductive layer.

According to various example embodiments of the present disclosure, the display device may further include: a gate insulation layer between the first conductive layer and the second conductive layer; an insulation layer between the second conductive layer and the third conductive layer; and a protection layer, and the insulation layer and the protection layer may not be disposed in the trench area.

According to various example embodiments of the present disclosure, the display device may further include: a bank between the third conductive layer and the cathode electrode, and the bank may not be disposed in the trench area.

According to various example embodiments of the present disclosure, the gate signal supply pad may include: a first pad part; and a second pad part on the first pad part, and the first pad part may be disposed at the second conductive layer, and the second pad part may be disposed at the third conductive layer.

According to various example embodiments of the present disclosure, the display panel may further include: a first ground voltage supply line that connects the first ground voltage supply pad and the trench pixel electrode to each other; and a gate signal supply line that connects the gate signal supply pad and the gate driving circuit to each other, and the first ground voltage supply pad may be disposed outside the gate signal supply pad.

According to various example embodiments of the present disclosure, the gate signal supply line may include: a first gate signal supply line connected to the gate signal supply pad; and a second gate signal supply line that connects the first gate signal supply line and the gate driving circuit to each other, and the second gate signal supply line may be disposed at a first conductive layer, the first gate signal supply line may be disposed at a second conductive layer that is on the first conductive layer, the trench pixel electrode may be disposed at a third conductive layer that is on the second conductive layer, the cathode electrode may be disposed at the third conductive layer, the first ground voltage supply line may include: a first-first ground voltage supply line connected to the first ground voltage supply pad; and a first-second ground voltage supply line connected to the first-first ground voltage supply line and the trench pixel electrode, the first-first ground voltage supply line may be disposed at the second conductive layer, and the first-second ground voltage supply line may be disposed at the third conductive layer.

According to various example embodiments of the present disclosure, the display device may further include: a first ground voltage pad for being electrically connected to the first source film; a second ground voltage pad for being electrically connected to the second source film; and an upper pixel electrode disposed between the first or second source film and the display area, and the upper pixel electrode may be electrically connected to the first ground voltage pad and the second ground voltage pad, and the upper pixel electrode may be electrically connected to the cathode electrode.

According to various example embodiments of the present disclosure, the first source film may be disposed outside the second source film.

Another example embodiment is a display device, including: a display panel including: a display area; a non-display area disposed outside or around the display area; and a source film configured to supply a ground voltage to the display panel. The source film may be attached to or on the non-display area. The display panel may include: a substrate; a first ground voltage supply pad and a second ground voltage supply pad disposed on the substrate and configured to receive the ground voltage from the source film; an upper electrode disposed between the source film and the display area and for being electrically connected to the second ground voltage supply pad; a trench electrode disposed in a trench area of the non-display area and for being electrically connected to the first ground voltage supply pad; and a cathode electrode disposed on the upper electrode and the trench electrode, and the upper electrode and the trench electrode may be electrically connected to the cathode electrode.

According to various example embodiments of the present disclosure, the display panel may further include: a gate driving circuit between the trench area and the display area; and a gate signal supply pad disposed at one side of the first ground voltage supply pad and for being electrically connected to the source film, and the gate signal supply pad may be electrically connected to the gate driving circuit.

According to various example embodiments of the present disclosure, the display panel may further include: a first ground voltage supply line that connects the first ground voltage supply pad and the trench electrode to each other; and a gate signal supply line that connects the gate signal supply pad and the gate driving circuit to each other, and the first ground voltage supply line and the gate signal supply line may intersect each other on a plane, and the first ground voltage supply line may be disposed on a layer which is different from a layer on which the gate signal supply line is disposed.

According to various example embodiments of the present disclosure, the display panel may further include: a first ground voltage supply line that connects the first ground voltage supply pad and the trench electrode to each other; and a gate signal supply line that connects the gate signal supply pad and the gate driving circuit to each other, and the first ground voltage supply pad may be disposed outside the gate signal supply pad.

Although embodiments of the present invention have been described for illustrative purposes, those skilled in the art will appreciate that various modifications, additions, and substitutions are possible, without departing from the scope and spirit of the invention as disclosed in the accompanying claims. Therefore, the embodiments disclosed in the present invention are intended to illustrate the scope of the technical idea of the present invention, and the scope of the present invention is not limited by the embodiment. The scope of the present invention shall be construed on the basis of the accompanying claims in such a manner that all of the technical ideas included within the scope equivalent to the claims belong to the present invention. The scope of protection of the present disclosure should be construed based on the following claims, and all technical features within the scope of equivalents thereof should be construed as being included within the scope of the present disclosure.

### EXAMPLE REFERENCE NUMERALS

The following reference numerals are provided as examples without limiting the scope of the present disclosure:
10, 11, 12: display device
SPCB1, SPCB2: first source printed circuit board, second source printed circuit board
CPCB: control printed circuit board
FFCa, FFCb, FFCc, FFCd: flexible flat cable
SF: source film
800: trench area

What is claimed is:

1. A display device, comprising:
a display panel comprising a display area;
a non-display area disposed outside the display area; and
a first source film and a second source film attached to the non-display area,
wherein the display panel comprises:
a substrate;
a first ground voltage supply pad disposed on the substrate and for being electrically connected to the first source film;
a trench pixel electrode for being electrically connected to the first ground voltage supply pad and disposed in a trench area of the non-display area; and
a cathode electrode on the substrate, and
wherein the cathode electrode is for being electrically connected to the trench pixel electrode in the trench area.

2. The display device of claim 1,
wherein the display panel further comprises:
a gate driving circuit between the trench area and the display area; and
a gate signal supply pad disposed at one side of the first ground voltage supply pad and for being electrically connected to the first source film, and
wherein the gate signal supply pad is for being electrically connected to the gate driving circuit.

3. The display device of claim 2,
wherein the display panel further comprises:
a first ground voltage supply line that connects the first ground voltage supply pad and the trench pixel electrode to each other; and
a gate signal supply line that connects the gate signal supply pad and the gate driving circuit to each other, and
wherein the first ground voltage supply line and the gate signal supply line intersect each other on a plane.

4. The display device of claim 3,
wherein the first ground voltage supply line is disposed on a layer which is different from a layer on which the gate signal supply line is disposed.

5. The display device of claim 4,
wherein the gate signal supply line comprises:
a first gate signal supply line connected to the gate signal supply pad; and
a second gate signal supply line that connects the first gate signal supply line and the gate driving circuit to each other,
wherein the second gate signal supply line is disposed at a first conductive layer,
wherein the first gate signal supply line is disposed at a second conductive layer, and
wherein the second conductive layer is on the first conductive layer.

6. The display device of claim 5,
wherein the trench pixel electrode is disposed at a third conductive layer,
wherein the third conductive layer is on the second conductive layer, and
wherein the cathode electrode is disposed on the third conductive layer.

7. The display device of claim 6,
wherein the first ground voltage supply line comprises:
a first-first ground voltage supply line connected to the first ground voltage supply pad;
a first-second ground voltage supply line connected to the first-first ground voltage supply line; and
a first-third ground voltage supply line connected to the first-second ground voltage supply line and the trench pixel electrode,
wherein the first-first ground voltage supply line is disposed at the second conductive layer,
wherein the first-second ground voltage supply line is disposed at the first conductive layer, and
wherein the first-third ground voltage supply line is disposed at the third conductive layer.

8. The display device of claim 7,
wherein the first-third ground voltage supply line and the second gate signal supply line intersect each other.

9. The display device of claim 6,
wherein the first ground voltage supply line comprises:
a first-first ground voltage supply line connected to the first ground voltage supply pad;
a first-second ground voltage supply line connected to the first-first ground voltage supply line; and
a first-third ground voltage supply line connected to the first-second ground voltage supply line and the trench pixel electrode,
wherein the first-first ground voltage supply line is disposed at the second conductive layer,
wherein the first-second ground voltage supply line is disposed at the first conductive layer, and
wherein the first-third ground voltage supply line is disposed at the second conductive layer.

10. The display device of claim 6, further comprising:
a gate insulation layer between the first conductive layer and the second conductive layer;
an insulation layer between the second conductive layer and the third conductive layer; and
a protection layer,
wherein the insulation layer and the protection layer are not disposed in the trench area.

11. The display device of claim 10, further comprising:
a bank between the third conductive layer and the cathode electrode,
wherein the bank is not disposed in the trench area.

12. The display device of claim 6,
wherein the gate signal supply pad comprises:
a first pad part; and
a second pad part on the first pad part,
wherein the first pad part is disposed at the second conductive layer, and
wherein the second pad part is disposed at the third conductive layer.

13. The display device of claim 2,
wherein the display panel further comprises:
a first ground voltage supply line that connects the first ground voltage supply pad and the trench pixel electrode to each other; and
a gate signal supply line that connects the gate signal supply pad and the gate driving circuit to each other, and
wherein the first ground voltage supply pad is disposed outside the gate signal supply pad.

14. The display device of claim 13,
wherein the gate signal supply line comprises:
a first gate signal supply line connected to the gate signal supply pad; and
a second gate signal supply line that connects the first gate signal supply line and the gate driving circuit to each other,
wherein the second gate signal supply line is disposed at a first conductive layer,
wherein the first gate signal supply line is disposed at a second conductive layer that is on the first conductive layer,
wherein the trench pixel electrode is disposed at a third conductive layer that is on the second conductive layer,
wherein the cathode electrode is disposed at the third conductive layer,
wherein the first ground voltage supply line comprises:
a first-first ground voltage supply line connected to the first ground voltage supply pad; and
a first-second ground voltage supply line connected to the first-first ground voltage supply line and the trench pixel electrode,
wherein the first-first ground voltage supply line is disposed at the second conductive layer, and
wherein the first-second ground voltage supply line is disposed at the third conductive layer.

15. The display device of claim 1, further comprising:
a first ground voltage pad for being electrically connected to the first source film;
a second ground voltage pad for being electrically connected to the second source film; and
an upper pixel electrode disposed between the first or second source film and the display area,
wherein the upper pixel electrode is for being electrically connected to the first ground voltage pad and the second ground voltage pad, and
wherein the upper pixel electrode is for being electrically connected to the cathode electrode.

16. The display device of claim 1,
wherein the first source film is disposed outside the second source film.

17. A display device, comprising:
a display panel comprising:
a display area;
a non-display area disposed outside the display area; and
a source film configured to supply a ground voltage to the display panel,
wherein the source film is attached to the non-display area,
wherein the display panel comprises:
a substrate;
a first ground voltage supply pad and a second ground voltage supply pad disposed on the substrate and configured to receive the ground voltage from the source film;
an upper electrode disposed between the source film and the display area and for being electrically connected to the second ground voltage supply pad;
a trench electrode disposed in a trench area of the non-display area and for being electrically connected to the first ground voltage supply pad; and
a cathode electrode disposed on the upper electrode and the trench electrode, and
wherein the upper electrode and the trench electrode are for being electrically connected to the cathode electrode.

18. The display device of claim 17,
wherein the display panel further comprises:
a gate driving circuit between the trench area and the display area; and
a gate signal supply pad disposed at one side of the first ground voltage supply pad and for being electrically connected to the source film, and
wherein the gate signal supply pad is for being electrically connected to the gate driving circuit.

19. The display device of claim 18,
wherein the display panel further comprises:
a first ground voltage supply line that connects the first ground voltage supply pad and the trench electrode to each other; and
a gate signal supply line that connects the gate signal supply pad and the gate driving circuit to each other,
wherein the first ground voltage supply line and the gate signal supply line intersect each other on a plane, and
wherein the first ground voltage supply line is disposed on a layer which is different from a layer on which the gate signal supply line is disposed.

20. The display device of claim 18,
wherein the display panel further comprises:
a first ground voltage supply line that connects the first ground voltage supply pad and the trench electrode to each other; and
a gate signal supply line that connects the gate signal supply pad and the gate driving circuit to each other, and
wherein the first ground voltage supply pad is disposed outside the gate signal supply pad.
